(19) United States
(12) Patent Application Publication
(10) Pub. No.: US 2012/0223782 A1
(43) Pub. Date: Sep. 6, 2012

(54) COMPLEX NEGATIVE FEEDBACK FREQUENCY SELECTION OUTPUT CIRCUIT AND OSCILLATION CIRCUIT USING THE SAME

(75) Inventor: Koichi Hirama, Hiratsuka-Shi (JP)

(73) Assignee: MARCDEVICES CO., LTD., Hiratsuka-shi, Kanagawa (JP)

(21) Appl. No.: 13/321,481

(22) PCT Filed: Aug. 31, 2011
(86) PCT No.: PCT/JP2011/069757

§ 371 Date: Nov. 18, 2011

(30) Foreign Application Priority Data
Mar. 4, 2011 (JP) 2011-047961

(51) Int. Cl. H03B 5/12

(52) U.S. Cl. 331/108 R

(57) ABSTRACT

It is an object to provide a complex negative feedback frequency selection output circuit that can produce an output signal of a high resonance sharpness Q factor and an oscillation circuit using the same. The complex negative feedback frequency selection output circuit according to the present invention, frequency-selectively relays only the residual components of one of a signal in phase with (or a signal opposite in phase to) a feedback processed signal obtained by negative feeding back a feedback signal to an input frequency signal, with a rejected frequency band being left out, while relaying at least a real number component of the other, and comprises a feedback path which relays a difference signal between (or a sum signal of) the selectively relayed output and the relayed output of the real number component, as the feedback signal. The gain of a loop including this feedback path is variable and can be set manually or automatically.

### TECHNICAL FIELD

The present invention relates to a resonant circuit, that is, a frequency selection output circuit and an oscillation circuit using the same.

### BACKGROUND ART

In order to obtain a stable frequency output signal that meets the market requirements in a simple and convenient manner, small-size piezoelectric oscillators using a “resonance phenomenon” such as a crystal resonator are widely used. As a method using the “resonance phenomenon”, Non-Patent Literature 1 discloses a technique of improving the resonance sharpness by incorporating a crystal resonator in a half bridge circuit. However, because an amplifier having a high gain is needed, there is the problem that an unexpected abnormal oscillation such as a spurious oscillation occurs, resulting in good short-term stability being not obtained.

Meanwhile, in small-size portable radio apparatuses, a piezoelectric oscillator having two outputs opposite in phase with respect to each other may be used for the purpose of taking an anti-noise measure. For example, Patent Literature 1 discloses a cross-coupled oscillation circuit where an oscillation circuit using an “anti-resonant phenomenon” and having two outputs opposite in phase with respect to each other is realized with a minimum number of transistors.

However, there are the following problems with the oscillation circuit disclosed in Patent Literature 1.

(1) Because the sharpness of resonance (effective Q factor) of the oscillation circuit at operation degrades more than the unloaded Q factor of the piezoelectric resonator being used, an oscillation output having good short-term stability cannot be obtained.

(2) It is not easy to adjust the frequency stably. Since the gain of the amplifier in use needs to be increased, a low noise characteristic or a low power consumption characteristic cannot be desired.

(3) Stray capacitance, residual inductance, or the like, which is inevitable with small-size high-density packaging, causes performance degradation.

(4) The influence of the parallel capacitance when a piezoelectric resonator is used puts a limit to the performance.

In summary, in conventional circuits, the effective Q factor of the resonant circuit is subject to the physical constants of its resonant element consisting of, e.g., a coil and a capacitor, and hence the effective Q factor cannot be improved unless these physical constants are changed.

### CITATION LIST

### Patent Literature

Patent Literature 1: Japanese Patent Kokai No. 2009-218871

### Non-Patent Literature

Non-Patent Literature 1: Robert J. Matthys; “Crystal Oscillator Circuit”, KRIEGER PUBLISHING COMPANY, FLORIDA, pp. 227-234, 1992.

### SUMMARY OF THE INVENTION

### Problem to be Solved by the Invention

An object of the present invention is to provide a resonant circuit that outputs without the resonance sharpness Q factor being degraded in a unloaded state and an oscillation circuit using the same.

### Means for Solving the Problem

A complex negative feedback frequency selection output circuit according to the present invention comprises a power distribution negative feedback circuit that has one input terminal, two output terminals, and a feedback terminal and outputs onto each of the two output terminals a signal in phase with (or a signal opposite in phase to) a feedback processed signal obtained by negative feeding back a feedback signal supplied to the feedback terminal to an input frequency signal supplied to the input terminal; a selective relay circuit that relays only the residual components of the output on one of the output terminals with a rejected frequency band being left out; a real number component relay circuit that relays at least a real number component of the output on the other of the output terminals; and a feedback circuit that relays a difference signal between (or a sum signal of) the relayed output of the selective relay circuit and the relayed output of the real number component relay circuit, as the feedback signal to the feedback terminal.

An adjustable complex negative feedback frequency selection output circuit according to the present invention comprises the above complex negative feedback frequency selection output circuit and loop gain adjusting means that adjusts the loop gain of a circuit loop from the input terminal to the feedback terminal.

An oscillation circuit according to the present invention-comprises the above complex negative feedback frequency selection output circuit or the above adjustable complex negative feedback frequency selection output circuit; and a positive feedback path that feeds back as the input frequency signal one of the in-phase output signal and the reverse-phase output signal outputted from the two output terminals of the power distribution negative feedback circuit.

### Advantageous Effects of Invention

With the complex negative feedback frequency selection output circuit of the present invention, an output signal of a high effective resonance sharpness Q factor when unloaded can be obtained.

With the adjustable complex negative feedback frequency selection output circuit of the present invention, in addition to the above effect, the resonance frequency and effective Q factor of a resonant circuit can be adjusted manually or automatically so as to be maintained at target set values.

With the oscillation circuit of the present invention, keeping the advantages of the complex negative feedback frequency selection output circuit or the adjustable complex negative feedback frequency selection output circuit, the sharpness of the oscillation frequency and oscillation output can be improved by adjusting the feedback rate of the positive feedback circuit.

### BRIEF DESCRIPTION OF DRAWINGS

FIG. 1 is a circuit diagram of a complex negative feedback frequency selection output circuit that is an embodiment of the present invention;

FIG. 2 is a graph showing simulation results of the output amplitude of the complex negative feedback frequency selection output circuit shown in FIG. 1;

FIG. 3 is a graph showing simulation results of the output phase of the complex negative feedback frequency selection output circuit shown in FIG. 1;

FIGS. 4(a) to 4(b) are circuit diagrams showing variants of a power distribution negative feedback circuit of the complex negative feedback frequency selection output circuit shown in FIG. 1;

FIGS. 4(c) to 4(d) are circuit diagrams showing variants of the power distribution negative feedback circuit of the complex negative feedback frequency selection output circuit shown in FIG. 1;

FIGS. 4(e) to 4(f) are circuit diagrams showing variants of the power distribution negative feedback circuit of the complex negative feedback frequency selection output circuit shown in FIG. 1;

FIGS. 5(a) to 5(g) are circuit diagrams showing variants of a resonator circuit of the complex negative feedback frequency selection output circuit shown in FIG. 1;

FIGS. 5(h) to 5(j) are circuit diagrams showing variants of the resonator circuit of the complex negative feedback frequency selection output circuit shown in FIG. 1;

FIGS. 6(a) to 6(f) are circuit diagrams showing variants of a compensation circuit of the complex negative feedback frequency selection output circuit shown in FIG. 1;

FIG. 6(g) is a circuit diagram showing a variant of the compensation circuit of the complex negative feedback frequency selection output circuit shown in FIG. 1;

FIGS. 7(a) to 7(c) are circuit diagrams showing variants of a first equivalent load circuit of the complex negative feedback frequency selection output circuit shown in FIG. 1;

FIGS. 8(a) to 8(c) are equivalent circuit diagrams of the complex negative feedback frequency selection output circuit according to the present invention;

FIGS. 8(d) to 8(e) are equivalent circuit diagrams of the complex negative feedback frequency selection output circuit according to the present invention;

FIG. 9 is a circuit diagram of an oscillation circuit including the complex negative feedback frequency selection output circuit shown in FIG. 1;

FIG. 10 is a block diagram of an adjustable complex negative feedback frequency selection circuit that is an embodiment of the present invention;

FIG. 11 is a circuit diagram of the complex negative feedback frequency selection output circuit 1 shown in FIG. 1;

FIG. 12 shows simulation results of the output phase of the complex negative feedback frequency selection output circuit 1 shown in FIG. 11;

FIG. 13 is a block diagram of an automatic adjustment circuit used in FIG. 10;

FIG. 14 is a circuit diagram of an oscillation circuit using the adjustable complex negative feedback frequency selection circuit shown in FIG. 1; and

FIG. 15 is a circuit diagram of a phase switching circuit forming part of the oscillation circuit shown in FIG. 14.

### DESCRIPTION OF EMBODIMENTS

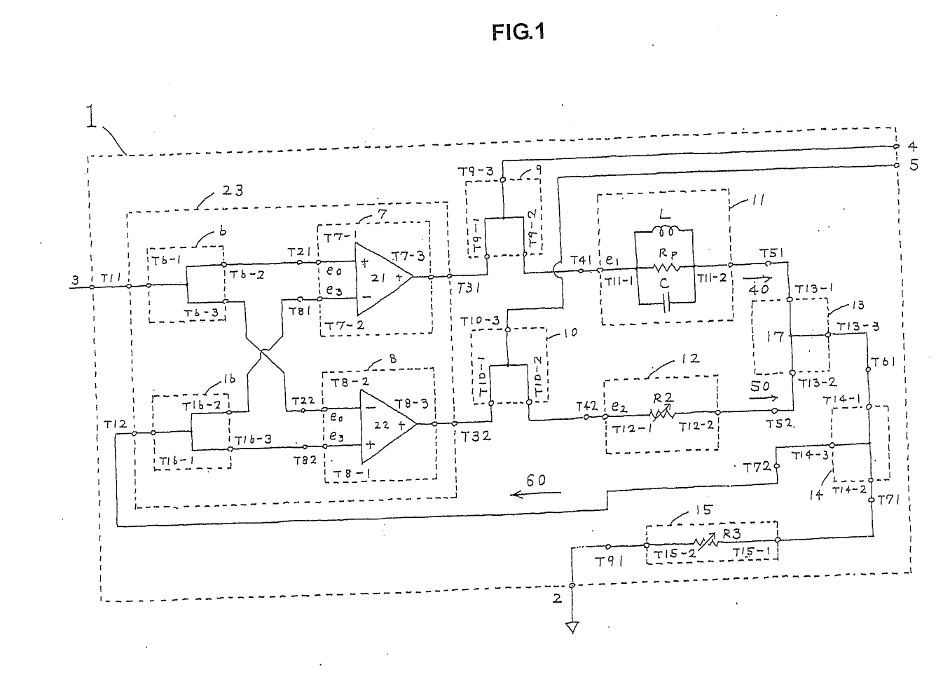

In FIG. 1, a complex negative feedback frequency selection output circuit 1 has a reference terminal 2, an input terminal 3, and output terminals 4, 5. The reference terminal 2 is connected to a reference potential such as a power supply potential, a predetermined intermediate potential, or a ground potential.

A power distribution negative feedback circuit 23 has an input terminal T11, a feedback terminal T12, an in-phase output terminal T31, a reverse-phase output terminal T32, a first power distribution circuit 6, a first operational amplifying circuit 7, a second power distribution circuit 16, and a second operational amplifying circuit 8.

The input terminal T11 of the power distribution negative feedback circuit 23 is connected to, e.g., a reference signal generator (not shown) via the input terminal 3. The reference signal generator is, for example, a device that generates an input frequency signal having its output maintained constant and whose frequency f is variable with, e.g., 10 MHz as the center. The input frequency signal from the reference signal generator is applied to the input terminal T11 of the power distribution negative feedback circuit 23. A feedback signal from a first analog adder circuit 13 is applied to the feedback terminal T12 of the power distribution negative feedback circuit 23.

The first power distribution circuit 6 has an input terminal T6-1 connected to the input terminal T11, and first and second output terminals T6-2, T6-3 connected to the input terminal T6-1. In the first power distribution circuit 6, the input signal inputted to the input terminal T6-1 is distributed to and output onto the first and second output terminals T6-2, T6-3 with maintaining its signal level and phase. Let e0 be the level of the distributed outputted signal.

The fifth power distribution circuit 16 has an input terminal T16-1 connected to the feedback terminal T12, and first and second output terminals T16-2, T16-3. In the fifth power distribution circuit 16, the input signal inputted to the input terminal T16-1 is distributed to and output onto the first and second output terminals T16-2, T16-3 with its signal level and phase maintained. Let e3 be the level of the distributed outputted signal.

The first operational amplifying circuit 7 has an in-phase input terminal T7-1, a reverse-phase input terminal T7-2, and a positive-phase output terminal T7-3. The in-phase input terminal T7-1 is connected to the first output terminal T6-2 of the first power distribution circuit 6. The reverse-phase input terminal T7-2 is connected to the first output terminal T16-2 of the fifth power distribution circuit 16.

The first operational amplifying circuit 7 comprises a phase non-inverting circuit that maintains the phase of the input signal supplied to the in-phase input terminal T7-1 with amplifying the level of that input signal with a gain μa1, a phase inverting circuit that inverts the phase of the input signal supplied to the reverse-phase input terminal T7-2 with amplifying the level of that input signal with a gain μb1, and an analog adder circuit that adds the output signals in analog of the phase non-inverting circuit and of the phase inverting circuit. Note that the gain pal of the phase inverting circuit and the gain μb1 of the phase non-inverting circuit can be set to be either substantially equal or different. The μa1 and the μb1 are taken as the ratio of the signal level e1 supplied to the terminal T11-1 of a resonator circuit 11 to the signal level e0 supplied to the in-phase input terminal T7-1 of the first operational amplifying circuit 7 and taken as the gain μ1 of the first differential input amplifying circuit 7.

The second differential input amplifying circuit 8 has an in-phase input terminal T8-1, a reverse-phase input terminal T8-2, and a positive-phase output terminal T8-3. The in-phase input terminal T8-1 is connected to the second output terminal T16-3 of the second power distribution circuit 16, and the reverse-phase input terminal T8-2 is connected to the second output terminal T6-3 of the first power distribution circuit 6.

The second differential input amplifying circuit 8 comprises a phase non-inverting circuit that maintains the phase of the input signal supplied to the in-phase input terminal T8-1 with amplifying the level of that input signal with a gain μa2, a phase inverting circuit that inverts the phase of the input signal supplied to the reverse-phase input terminal T8-2 with amplifying the level of that input signal with a gain μb2, and an analog adder circuit that adds the output signals in analog of the phase non-inverting circuit and of the phase inverting circuit. The gain μa2 of the phase inverting circuit and the gain μb2 of the phase non-inverting circuit can be set to be either substantially equal or different. The μa2 and the μb2 are taken as the ratio of the signal level e2 supplied to the terminal T12-1 of a compensating circuit 12 to a phase-inverted signal level from the signal level e0 supplied to the reverse-phase input terminal T8-2 of the second differential input amplifying circuit 8 and taken as the gain μ2 of the second differential input amplifying circuit 8.

A second power distribution circuit 9 has an input terminal T9-1 and first and second output terminals T9-2, T9-3. The input terminal T9-1 is connected to the in-phase output terminal T31 of the power distribution negative feedback circuit 23. The first output terminal T9-2 is connected to the terminal T11-1 of the resonator circuit 11 via the terminal T41. The second output terminal T9-3 is connected to the first output terminal 4. The second power distribution circuit 9 distributes and outputs the input signal inputted to the input terminal T9-1 to and onto the first and second output terminals T9-2, T9-3 with its signal level and phase being maintained.

A third power distribution circuit 10 has an input terminal T10-1 and first and second output terminals T10-2, T10-3. The input terminal T10-1 is connected to the reverse-phase output terminal T32 of the power distribution negative feedback circuit 23. The first output terminal T10-2 is connected to the terminal T12-1 of the compensating circuit 12. The second output terminal T10-3 is connected to the second output terminal 5. The third power distribution circuit 10 distributes and outputs the input signal inputted to the input terminal T10-1 to and onto the first and second output terminals T10-2, T10-3 with its signal level and phase being maintained.

In the power distribution negative feedback circuit 23, the input frequency signal supplied via the input terminal 3 is inputted via the in-phase input terminal T11, and the feedback signal from the first analog adder circuit 13 is inputted via the reverse-phase input terminal T12. A signal in phase with the input frequency signal is output onto the in-phase output terminal T31, and a signal opposite in phase to the input frequency signal is output onto the reverse-phase output terminal T32.

The resonator circuit 11 has terminals T11-1 and T11-2 and is a parallel resonant circuit formed of a coil L, a capacitor C, and a resistor Rp connected in parallel between these terminals. The resonator circuit 11 has a NULL characteristic where its output is attenuated at the anti-resonance frequency fp. That is, the resonator circuit 11 relays only the residual components with a rejected frequency band being left out. Thus, a resonance output attenuated at the band at and around the anti-resonance frequency fp is output via the terminal T11-2 to the first analog adder circuit 13.

The compensating circuit 12 has terminals T12-1 and T12-2 and is a pure resistor circuit having a resistor R2 connected between these terminals. In the compensating circuit 12, the input signal supplied to the terminal T12-1 is output via the terminal T12-2 to the first analog adder circuit 13 with being attenuated in signal level through the resistor R2.

The first analog adder circuit 13 has a first input terminal T13-1, a second input terminal T13-2, and an output terminal T13-3. The first input terminal T13-1 is connected to the terminal T11-2 of the resonator circuit 11. The second input terminal T13-2 is connected to the terminal T12-2 of the compensating circuit 12. In the first analog adder circuit 13, the signals supplied to the first input terminal T13-1 and the second input terminal T13-2 are added in analog, and the sum is output via the output terminal T13-3 onto the terminal T61. The connection point of the three terminals T13-1, T13-2, T13-3 of the first analog adder circuit 13 is called a “first virtual analog addition point” 17. The level drop between the first virtual analog addition point 17 and the output terminal T13-3 of the first analog adder circuit 13 is negligibly small. Let e3 be the signal level at the first virtual analog addition point 17.

A fourth power distribution circuit 14 has an input terminal T14-1 and first and second output terminals T14-2, T14-3. The input terminal T14-1 is connected via the terminal T61 to the output terminal T13-3 of the first analog adder circuit 13. The first output terminal T14-2 is connected to the input terminal T15-1 of a first equivalent load circuit 15. The second output terminal T14-3 is connected via the terminal T72 to the feedback terminal T12 of the power distribution negative feedback circuit 23. In the fourth power distribution circuit 14, the signal supplied to the input terminal T14-1 is output onto the first and second output terminals T14-2 and T14-3.

The first equivalent load circuit 15 is a pure resistor circuit having an input terminal T15-1, an output terminal T15-2, and a resistor R3 connected between these terminals. The input terminal T15-1 is connected to the first output terminal T14-2 of the fourth power distribution circuit 14. The output terminal T15-2 is connected to the reference terminal 2.

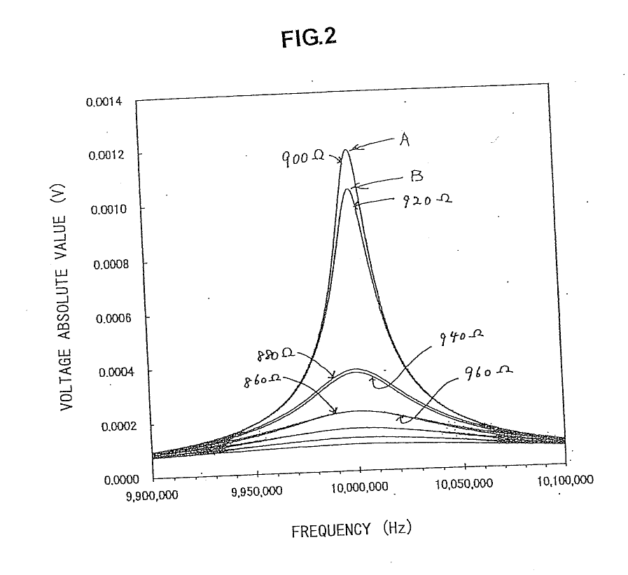

The action of the complex negative feedback frequency selection output circuit 1 of FIG. 1 will be described using FIG. 2. The simulation results of FIG. 2 were obtained when the voltage of the input frequency signal applied to the input terminal 3 of FIG. 1 was set at 1 μV and its frequency was swept from 9,900,000 Hz to 10,100,000 Hz. The gain μ1 of the first operational amplifying circuit 7, the gain μ2 of the second operational amplifying circuit 8, and the circuit constants of the resonator circuit 11, the compensating circuit 12, and the first equivalent load circuit 15 were set as shown in Table 1.

TABLE 1

| | |
|---|---|
| Resonator Circuit | fp = 10 MHz |
| | L = 25 μH |
| | C = 10.13211 pF |
| | Rp = 15.707 kΩ |
| Compensating Circuit | R2 = 5 kΩ |
| 1st Equivalent Load Circ. | R3 = 800 Ω to 1000 Ω |
| Gain | μ1 = 10 |
| | μ2 = 10 |

The horizontal axis of FIG. 2 represents the frequency (Hz) of the input frequency signal applied to the input terminal 3 of FIG. 1, and the vertical axis represents the absolute value (V: volts) of the voltage occurring on the positive-phase output terminal T7-3 of the first operational amplifying circuit 7, that is, the first output terminal 4. As shown in FIG. 2, when the resistance R3 of the first equivalent load circuit 15 was changed from 800Ω to 1000Ω in steps of 20Ω, the voltage occurring on the first output terminal 4 presented a peak against the frequency at a specific resistance value R3. Namely, the occurrence of a resonance phenomenon was obtained. In particular, the curve A is for R3=900Ω, and the curve B is for R3=920Ω.

The effective Q factor was calculated from the peak voltage value and the interval of the frequencies that the voltage value is equal to the peak voltage value divided by the square root of two. As a result, for the curve A, the effective Q factor is about 500, which value is about 50 times the Q value of the coil forming part of the resonator circuit 11. Hence, by using the complex negative feedback frequency selection output circuit 1, the Q value (the Q value when unloaded=10) of the resonator circuit 11 itself can be increased by about 50 times. Note that the absolute value of the voltage occurring on the second output terminal 5 is substantially the same as that on the first output terminal 4.

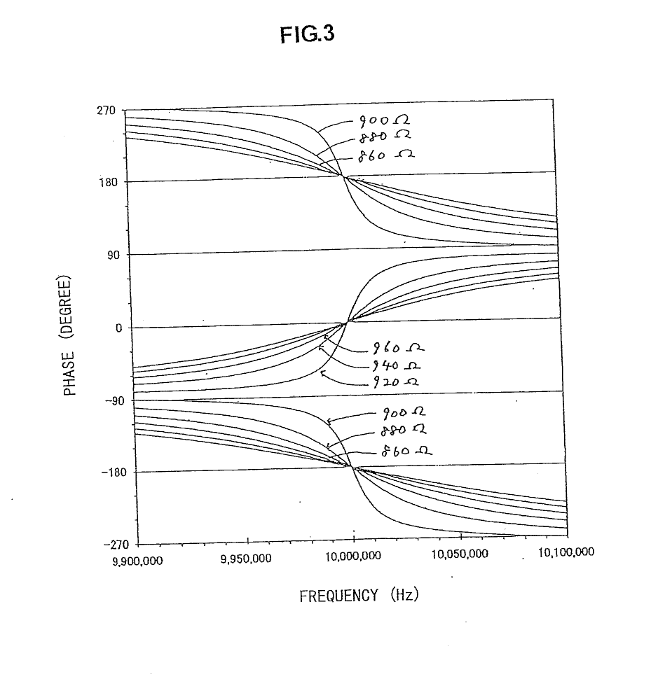

The further action of the complex negative feedback frequency selection output circuit 1 of FIG. 1 will be described using FIG. 3. The simulation results of FIG. 3 were obtained with the same settings as with the numerical simulation of FIG. 2. The horizontal axis of FIG. 3 represents the frequency (Hz) of the input frequency signal applied to the input terminal 3 of FIG. 1. The vertical axis represents the phase value (°) of the output signal occurring on the first output terminal 4 with respect to the phase value of the input frequency signal applied to the input terminal 3 of FIG. 1. The phase value of the output signal occurring on the first output terminal 4 being zero means that the phase of the output signal occurring on the first output terminal 4 and the phase of the input frequency signal are in phase. As shown in FIG. 2, when the resistance R3 of the first equivalent load circuit 15 was changed from 800Ω to 1000Ω in steps of 20Ω, several characteristic phenomena occurred.

First, when the value of R3 is changed from 800Ω to 1000Ω in steps of 20Ω with the phase of the input frequency signal inputted to the input terminal 3 being constant, the output signal occurring on the first output terminal 4 takes on two values of 0° and −180° at the anti-resonance frequency fp of the resonator circuit 11.

Second, although not shown, in the same way as in the first, the phase of the signal on the second output terminal 5 also takes on two values of −180° and 0° when the value of R3 is changed.

Third, the gradient obtained by dividing the phase change by the frequency change turns inverted depending on the value of the resistance R3.

Fourth, two outputs opposite in phase to each other, that is, in phase inverted relation are produced on the first output terminal 4 and the second output terminal 5.

Fifth, the phase of the input frequency signal supplied to the input terminal 3 can be controlled by the value of the resistance R3.

Note that the above first and fourth phenomena occur even when the value of the resistance R2 of the compensating circuit 12 is changed with the value of the resistance R3 of the first equivalent load circuit 15 being fixed.

The operation principle of the complex negative feedback frequency selection output circuit 1 shown in FIGS. 2 and 3 will be described using equations.

The ratio of the voltage e0 on the in-phase input terminal T7-1 of the first operational amplifying circuit 7 to the voltage e1 on the in-phase output terminal T7-3 of the first operational amplifying circuit 7 of the complex negative feedback frequency selection output circuit 1 of FIG. 1 is given by the equation 1.

$$\frac{{e}_{1}}{{e}_{0}} = \frac{{μ}_{1}}{{μ}_{1} + 1} + {( \frac{{μ}_{1}}{{μ}_{1} + 1} )}^{2} \frac{2 {y}_{2} + {y}_{3} - \frac{{μ}_{1} + 1}{{μ}_{1}} \frac{{μ}_{1} - {μ}_{2}}{{μ}_{1} - 1}}{{y}_{r} - \frac{{μ}_{1} - 1}{{μ}_{1} + 1} {y}_{2} + \frac{1}{{μ}_{1} + 1} {y}_{3} - \frac{{μ}_{1} - {μ}_{2}}{{μ}_{1} - 1} {y}_{2}} \qquad [ Expression 1 ]$$

Here, μ1 and μ2 are the gains of the first operational amplifying circuit 7 and the second operational amplifying circuit 8; yr, y2, y3 are the transfer admittance of the resonator circuit 11, the transfer admittance of the compensating circuit 12, and the admittance of the first equivalent load circuit 15 respectively. Although all the variables forming part of the equation 1 are generally not pure real numbers but complex numbers because of residual inductance, stray capacitance, transport time, and so on, here description will be made assuming that they are pure real numbers except for the transfer admittance yr of the resonator circuit 11.

In the equation 1, because the transfer admittance yr of the resonator circuit 11 is contained in its denominator, the effect of inverting the admittance occurs. That is, the gyrator effect of inverting the immittance occurs. Thus, the anti-resonance characteristic of the resonator circuit 11 is inverted to a resonance characteristic.

The transfer admittance yr of the resonator circuit 11 is generally expressed by the following equation.

yr=Re(yr)+Im(yr) [Expression 2]

Here, Re(yr) and Im(yr) are the real number component and the imaginary number component of the transfer admittance.

In the case of the resonator circuit 11 shown in FIG. 1, Re(yr) is the inverse of the resistance Rp. Im(yr) is the susceptance taken on by a parallel circuit of the inductance L of the coil and the capacitance C of the capacitor and takes on 0 (zero) at the anti-resonance frequency fp calculated from the inductance L and the capacitance C. The transfer admittance y2 of the compensating circuit 12 shown in FIG. 1 is a positive real number because R2 is assumed to be a pure resistor. The admittance y3 of the first equivalent load circuit 15 shown in FIG. 1 is a positive real number because R3 is assumed to be a pure resistor.

To put them all together, the numerator of the third term on the right side of the equation 1 always takes on a positive value because μ1=μ2 in this simulation. Meanwhile, in its denominator, because the imaginary number component Im(yr) is zero at the anti-resonance frequency, only the real number component remains with the imaginary number component being left out.

Let us pay attention to the fact that “−” (a minus sign) is affixed to the term containing y2 in the denominator of the third term on the right side of the equation 1. This means that the remaining real number component obtained by leaving out the imaginary number component from the complex number can take on a negative, zero, or positive value according to the relative relation between μ, y2, and y3.

This indicates that by changing R3, the effective Q factor is improved as shown in FIG. 2 and that the phase is inverted as shown in FIG. 3. The amplitude characteristic and the phase characteristic are both subject to the gains μ1 and μR2, the loss component y2 of the compensating circuit, and the loss component y3 of the first equivalent load circuit 15, exclusive of the loss component Re(yr) of the resonator circuit 11.

Here, the attributes of the transfer admittance yr of the resonator circuit 11, the transfer admittance y2 of the compensating circuit 12, and the admittance y3 of the equivalent load circuit 15 will be described in more detail. The state equation of the complex negative feedback frequency selection output circuit 1 is expressed by the equation 1, and the transfer admittance yr of the resonator circuit 11, the transfer admittance y2 of the compensating circuit 12, and the admittance y3 of the equivalent load circuit 15 are all a complex number. Also, the gains are complex numbers since the amplifiers have a phase delay between their input and output. In addition, these complex numbers include stray capacitance, residual inductance, and the like inevitably when mounted in a circuit.

Let us pay attention to the fact that in the denominator containing yr of the equation 1, there are merely added or subtracted yr, and y2 and y3 that have affixed thereto a coefficient that is a complex number and dependent on the gain. Description will be made assuming that μ1 and μ2 are equal, thus the fourth term of the denominator being zero.

Let us take y2 and y3 to include the results of computing the coefficients dependent on the gains. Then yr, y2, and y3 are all a complex number. When the real parts and imaginary parts of yr, y2, and y3, which are complex numbers, are separately added or subtracted, expressions Re(yr)−Re(y2)+Re(y3) and Im(yr)−Im(y2)+Im(y3) are obtained.

First, the sum of the real number components (loss components) will be described. The first term of Re(yr)−Re(y2)+Re(y3) is the conductance component of the resonator circuit 11 and is the inverse of the resistance component Rp. The second term thereof is the conductance component of the compensating circuit 12 and is the inverse of the compensation resistance component R2. The third term thereof is the conductance component of the equivalent load circuit 15 and is the inverse of the resistance component R3.

Because Re(y2) has a minus sign affixed thereto, Re(yr)−Re(y2)+Re(y3) can take on a negative, zero, or positive value. Thus, the effective Q factor can be controlled greatly. There is another method of controlling the effective Q factor greatly. That is, since y2 and y3 include the gains implicitly, the same is possible when the two gains are changed.

Second, the sum of the imaginary number components will be described. The first term of Im(yr)−Im(y2)+Im(y3) is the susceptance component taken on by a parallel circuit of the coil L and the capacitor C of the resonator circuit 11. The susceptance component of the compensating circuit 12 that is the second term and the susceptance component of the equivalent load circuit 15 that is the third term are both set to 0. By setting these components to 0, the two susceptance components can be incorporated into the susceptance component taken on by the resonator circuit 11 that is the first term.

Thus, by placing, for example, a reactance component in the equivalent load circuit that is the third term and changing its value, the equivalent constants of the resonator circuit 11 can be equivalently changed, without actually changing the equivalent constants of the circuit elements of the resonator circuit 11, and thus the anti-resonance (parallel resonance) frequency can be adjusted.

If the reactance elements (imaginary number components) of y2 and y3 exclusive of their resistance R are changed, it is only that the anti-resonance (parallel resonance) frequency changes, and the characteristics shown in FIGS. 2 and 3 are not presented.

The characteristics shown in FIGS. 2 and 3 can be presented when the resistance components (real number components) of y2 and y3 exclusive of the reactance elements (imaginary number components) are changed. Thus, by setting y2 and y3 to pure real numbers, the effective Q factor of the complex negative feedback frequency selection output circuit 1 shown in FIG. 1 can be increased.

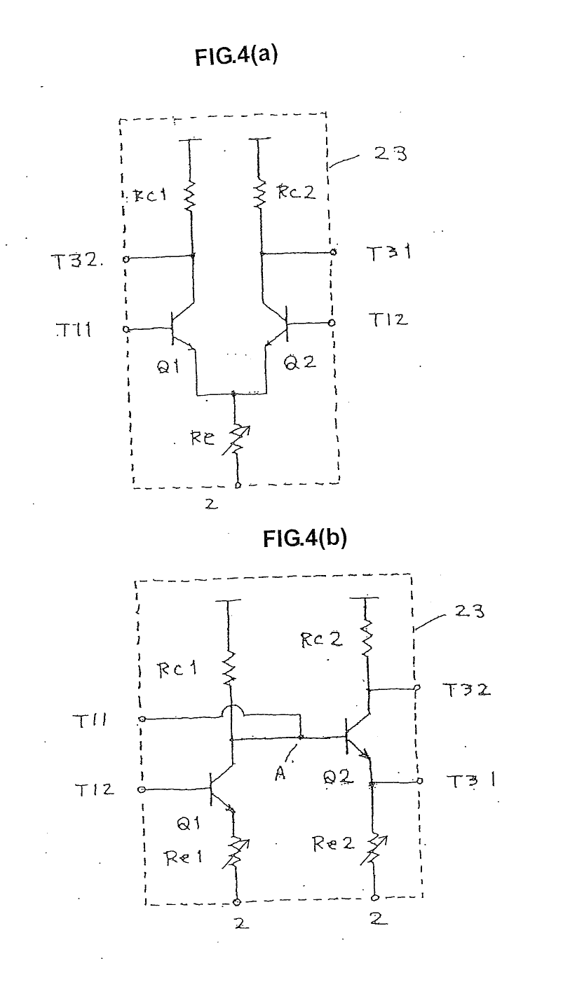

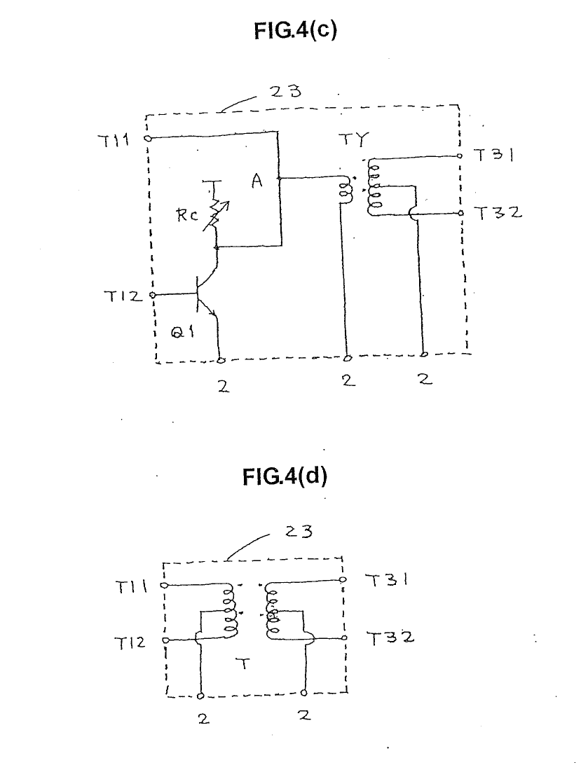

Variants of the power distribution negative feedback circuit 23 shown in FIG. 1 will be described using FIGS. 4(a) to 4(f). The terminal reference numerals correspond to those in FIG. 1.

As shown in FIG. 4(a), the power distribution negative feedback circuit 23 shown in FIG. 1 can be constituted by a differential pair amplifying circuit having transistors Q1 and Q2. The bases of the transistors Q1 and Q2 are connected to the in-phase input terminal T11 and the reverse-phase input terminal T12 respectively. The emitters of the transistors Q1 and Q2 are connected to the reference terminal 2 via a common resistor Re. The collectors of the transistors Q1 and Q2 are connected to the reverse-phase output terminal T32 and the in-phase output terminal T31 respectively.

In the power distribution negative feedback circuit 23 shown in FIG. 4(a), a signal in phase with the signal supplied via the in-phase input terminal T11 is generated at the collector of the transistor Q2 and is output onto the in-phase output terminal T31. A signal opposite in phase to the signal supplied via the in-phase input terminal T11 is generated at the collector of the transistor Q1 and is output onto the reverse-phase output terminal T32. Note that this differential pair amplifying circuit is formed of bipolar transistors and that a direct current bias resistor, a DC-cut capacitor, and the like are omitted from the figure.

With the power distribution negative feedback circuit 23 shown in FIG. 4(a), the input signal supplied to the in-phase input terminal T11 goes through the transistors Q1 and Q2, causing an in-phase signal for T31 and a reverse-phase signal for T32 to be output. The feedback signal that is the input to the feedback terminal T12 is negatively fed back via the transistors Q1 and Q2 to the in-phase signal on T31 and the reverse-phase signal on T32.

As shown in FIG. 4(b), the power distribution negative feedback circuit 23 can be formed of a front stage having a transistor Q1 and a rear stage having a transistor Q2. In the front stage, the base of the transistor Q1 is connected to the reverse-phase input terminal T12. The emitter of the transistor Q1 is connected to the reference terminal 2 via a resistor Re1. The collector of the transistor Q1 is connected to the in-phase input terminal T11 and the base of the transistor Q2. In the rear stage, the base of the transistor Q2 is connected to the in-phase input terminal T11 and the collector of the transistor Q1. The emitter of the transistor Q2 is connected to the in-phase output terminal T31 and via a resistor Re2 to the reference terminal 2. The collector of the transistor Q2 is connected to the reverse-phase output terminal T32.

In the front stage, the input signal to the reverse-phase input terminal T12 is supplied to the base of the transistor Q1, and a signal amplified and inverted in phase from the input signal to the reverse-phase input terminal T12 is generated at the collector of the transistor Q1. The signal generated at the collector of the transistor Q1 and the input signal to the in-phase input terminal T11 are added in analog at point A. In the rear stage, the added signal is applied to the base of the transistor Q2, and an in-phase output signal and a reverse-phase output signal are generated at the emitter and collector of the transistor Q2 respectively and output onto the in-phase output terminal T31 and the reverse-phase output terminal T32 respectively.

Thus, where the power distribution negative feedback circuit 23 is configured as shown in FIG. 4(b), in the complex negative feedback frequency selection output circuit 1 shown in FIG. 1, the input signal that is the input to T11 goes through the point A and the transistor Q2, causing an in-phase signal for T31 and a reverse-phase signal for T32 to be output. The feedback signal that is the input to the feedback terminal T12 is negatively fed back via the transistors Q1 and Q2 to the in-phase signal on T31 and the reverse-phase signal on T32. That is, a complex negative feedback circuit is formed. The power distribution negative feedback circuit 23 shown in FIG. 4(b) can be regarded as a combination of a differential-input differential-output circuit and an amplifying circuit without phase inversion between its input and output.

Where the power distribution negative feedback circuit 23 is configured as shown in FIG. 4(c), the base of the transistor Q1 is connected to the reverse-phase input terminal T12. The collector of the transistor Q1 is connected to the in-phase input terminal T11, a resistor Rc, and the positive input terminal on the primary side of a Yarman transformer TY. The negative input terminal on the primary side of the Yarman transformer TY is connected to the reference terminal 2. The positive and negative input terminals on the secondary side of the Yarman transformer TY are connected to the in-phase output terminal T31 and the reverse-phase output terminal T32 respectively. The signal from the in-phase input terminal T11 is supplied to point A that is the positive input terminal on the primary side of the Yarman transformer TY. An amplified and phase-inverted signal from the signal supplied to the base of the transistor Q1 via the reverse-phase input terminal T12 is supplied to the point A. These two signals are added in analog at the point A to be supplied to the positive input terminal on the primary side of the Yarman transformer TY and to be output via the positive and negative output terminals on the secondary side of the Yarman transformer TY onto the in-phase output terminal T31 and the reverse-phase output terminal T32. A mark “” in the transformer symbol indicates the positive pole side. The middle terminal on the secondary side of the Yarman transformer TY is connected to the reference terminal 2. The variant circuit shown in FIG. 4(c) may be used when an amplification function is placed in only a first negative feedback current path loop 70 and a second negative feedback current path loop 80.

Thus, where the power distribution negative feedback circuit 23 is configured as shown in FIG. 4(c), the input signal that is the input to T11 of the complex negative feedback frequency selection output circuit 1 shown in FIG. 1 is supplied via the point A to the input terminal on the primary side of the Yarman transformer TY, and an in-phase signal and a reverse-phase signal are output onto T31 and T32 via the output terminals on the secondary side of the same. Further, the feedback signal that is the input to the feedback terminal T12 is inverted in phase by the transistor Q1 and supplied to the point A, thereby negatively feeding back the in-phase signal on T31 and the reverse-phase signal on T32.

In the variant circuit of the power distribution negative feedback circuit 23 shown in FIG. 4(d), the primary winding of a transformer T has a positive input terminal, a primary side middle tap, and a negative input terminal. The secondary winding of the transformer has a positive output terminal, a secondary side middle tap, and a negative output terminal. This circuit is constituted by a transformer of a six terminal configuration having middle taps in both the primary winding and the secondary winding. A mark “” in the transformer symbol in FIG. 4(d) indicates the positive pole side. In the variant circuit shown in FIG. 4(d), the signal supplied via the in-phase input terminal T11 is inputted to the positive input terminal on the primary side of the transformer, and the signal supplied via the reverse-phase input terminal T12 is inputted to the negative input terminal on the secondary side of the transformer. The signal from the positive output terminal on the secondary side of the transformer is output onto the in-phase output terminal T31, and the signal from the negative output terminal on the secondary side of the transformer is output onto the reverse-phase output terminal T32. The variant circuit shown in FIG. 4(d) can be formed by combining a plurality of, e.g., λ/2 strip line resonant circuits arranged adjacent to each other.

In the power distribution negative feedback circuit 23 shown in FIG. 4(d), the input signal that is the input to T11 of the complex negative feedback frequency selection output circuit 1 shown in FIG. 1, via the transformer T, causes an in-phase signal and a reverse-phase signal to be output onto T31 and T32 respectively. The in-phase signal on T31 and the reverse-phase signal on T32 are negatively fed back via the transformer T and inputted as a feedback signal to the feedback terminal T12. The power distribution negative feedback circuit 23 shown in FIG. 4(d) is a differential-input differential-output circuit and does not have an amplification function. If necessary, a circuit having an amplification function may be placed in a predetermined part, e.g. a negative feedback current path 60, in the first negative feedback current path 70 or the second negative feedback current path 80.

A variant circuit of the power distribution negative feedback circuit 23 shown in FIG. 4(e) has a positive input terminal T11 and a negative input terminal T12 on the primary side thereof and a positive output terminal T31 and a negative output terminal T32 on the secondary side thereof. Micro-strip line resonant circuits a, b serially connected are connected between the positive input terminal T11 and the positive output terminal T31. Micro-strip line resonant circuits d, e serially connected are connected between the negative input terminal T12 and the negative output terminal T32. A micro-strip line resonant circuit c is connected between the middle point of the micro-strip line resonant circuits a, b and the middle point of the micro-strip line resonant circuits d, e. These five micro-strip line resonant circuits form a T-type circuit that is an example of a symmetrical ladder circuit.

In the power distribution negative feedback circuit 23 shown in FIG. 4(e), two λ/2 micro-strip line resonant circuits a and b are cascade-connected in the current path between the positive input terminal T11 and the positive output terminal T31, and hence a circuit having an effective propagation wavelength of X (one wavelength) is formed in this current path. In this case, the phases at the two terminals T11 and T31 are in phase. Two λ/2 micro-strip line resonant circuits d and e are cascade-connected in the current path between the negative input terminal T12 and the negative output terminal T32, and hence a circuit having an effective propagation wavelength of X (one wavelength) is formed in this current path. In this case, the signal phases at the two terminals T12 and T32 are in phase.

Three λ/2 micro-strip line resonant circuits a, c, e are cascade-connected in the current path between the positive input terminal T11 and the negative output terminal T32, and hence a circuit having an effective propagation wavelength of 3/2λ (1.5 wavelengths) is formed in this current path. In this case, the signal phases at the two terminals T11 and T32 are opposite.

Three λ/2 micro-strip line resonant circuits d, c, b are cascade-connected in the current path between the negative input terminal T12 and the positive output terminal T31, and hence a circuit having an effective propagation wavelength of 3/2λ (1.5 wavelengths) is formed in this current path. In this case, the signal phases at the two terminals T12 and T31 are opposite.

In the power distribution negative feedback circuit 23 shown in FIG. 4(e), the input signal to T11 of the complex negative feedback frequency selection output circuit 1 shown in FIG. 1, via the micro-strip line resonant circuits a, b and a, c, e, causes an in-phase signal to be output onto T31 and a reverse-phase signal to be output onto T32. The in-phase signal on T31 and the reverse-phase signal on T32 are negatively fed back and inputted as a feedback signal to the feedback terminal T12. The power distribution negative feedback circuit 23 shown in FIG. 4(e) is a differential-input differential-output circuit and does not have an amplification function. In this case, a circuit having an amplification function may be placed in a predetermined part, e.g. a negative feedback current path 60, in the first negative feedback current path 70 or the second negative feedback current path 80. Although the micro-strip line resonant circuits shown in FIG. 4(e) are all a λ/2 micro-strip line resonant circuit, the shape and size of the micro-strip line resonant circuit are not limited to this. That is, it may be formed of micro-strip line resonant circuits having an effective propagation wavelength of (n+1/2)λ, where n is one of natural numbers including zero.

A variant circuit of the power distribution negative feedback circuit 23 shown in FIG. 4(f) has a positive input terminal T11 and a negative input terminal T12 on the primary side thereof and a positive output terminal T31 and a negative output terminal T32 on the secondary side thereof. A λ/2 micro-strip line resonant circuit a is connected between the positive input terminal T11 and the negative input terminal T12. A λ/2 micro-strip line resonant circuit b is connected between the positive input terminal T11 and the negative output terminal T32. A λ/2 micro-strip line resonant circuit c is connected between the negative input terminal T12 and the positive output terminal T31. A λ/2 micro-strip line resonant circuit d is connected between the positive output terminal T31 and the negative output terminal T32.

In the power distribution negative feedback circuit 23 shown in FIG. 4(f), in the current path between the positive input terminal T11 and the positive output terminal T31, two λ/2 micro-strip line resonant circuits a and c are cascade-connected, and in addition two λ/2 micro-strip line resonant circuits b and d are cascade-connected. A circuit having an effective propagation wavelength of X (one wavelength) is formed between the two terminals T11 and T31. In this case, the phases at the two terminals T11 and T31 are in phase.

In the current path between the negative input terminal T12 and the negative output terminal T32, two λ/2 micro-strip line resonant circuits a and b are cascade-connected, and in addition two λ/2 micro-strip line resonant circuits c and d are cascade-connected. A circuit having an effective propagation wavelength of X (one wavelength) is formed between the two terminals T12 and T32. In this case, the signal phases at the two terminals T12 and T32 are in phase.

In the current path between the positive input terminal T11 and the negative output terminal T32, the λ/2 micro-strip line resonant circuit b is connected, and in addition three λ/2 micro-strip line resonant circuits a, c, and d are cascade-connected. Circuits having effective propagation wavelengths of λ/2 (0.5 wavelength) and 3/2λ (1.5 wavelengths) respectively are formed between the two terminals T11 and T32. In this case, the phases at the two terminals T11 and T32 are opposite.

In the current path between the negative input terminal T12 and the positive output terminal T31, the λ/2 micro-strip line resonant circuit c is connected. Circuits having effective propagation wavelengths of λ/2 (0.5 wavelength) and 3/2λ (1.5 wavelengths) respectively are formed between the two terminals T12 and T31. In this case, the signal phases at the two terminals T12 and T31 are opposite.

In the variant circuit of the power distribution negative feedback circuit 23 shown in FIG. 4(f), the signal supplied via the in-phase input terminal T11 is supplied to the positive input terminal T11 on the primary side of the micro-strip line complex circuit, and the signal supplied via the reverse-phase input terminal T12 is supplied to the negative input terminal on the secondary side of the micro-strip line complex circuit. The signal from the positive output terminal on the secondary side of the micro-strip line complex circuit is output onto the in-phase output terminal T31, and the signal from the negative output terminal on the secondary side of the micro-strip line complex circuit is output onto the reverse-phase output terminal T32.

Thus, with the power distribution negative feedback circuit 23 shown in FIG. 4(f), in the complex negative feedback frequency selection output circuit 1 shown in FIG. 1, the input signal that is the input to T11, via the micro-strip line resonant circuits a, c, and b, causes an in-phase signal for T31 and a reverse-phase signal for T32 to be output. The feedback signal that is the input to the feedback terminal T12 is negatively fed back to the in-phase signal on T31 and the reverse-phase signal on T32 via the micro-strip line resonant circuits c and c, d.

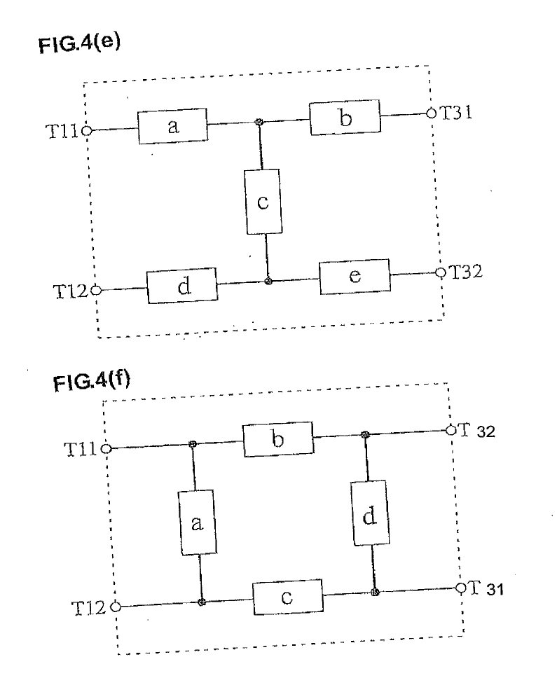

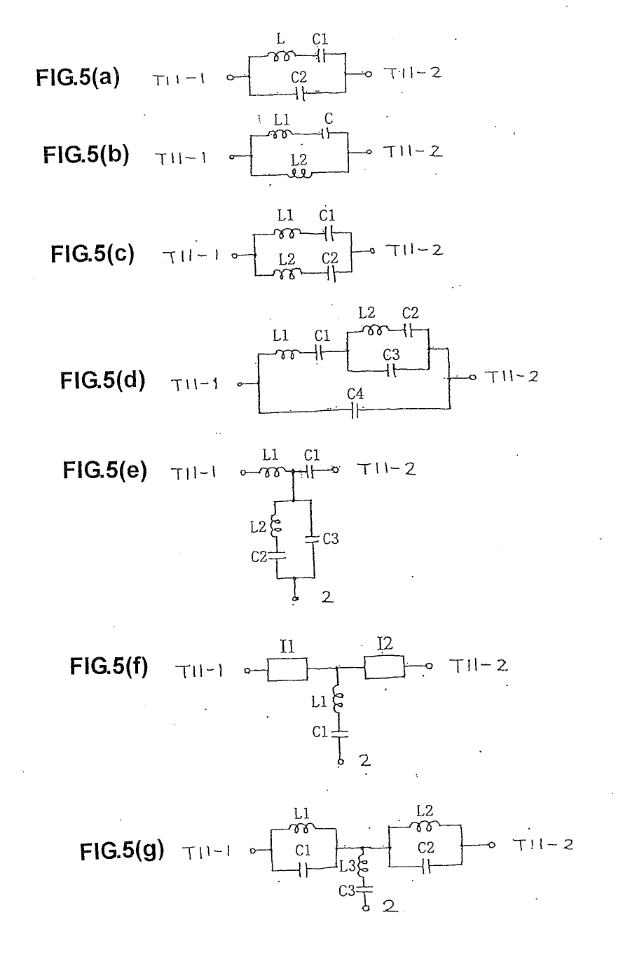

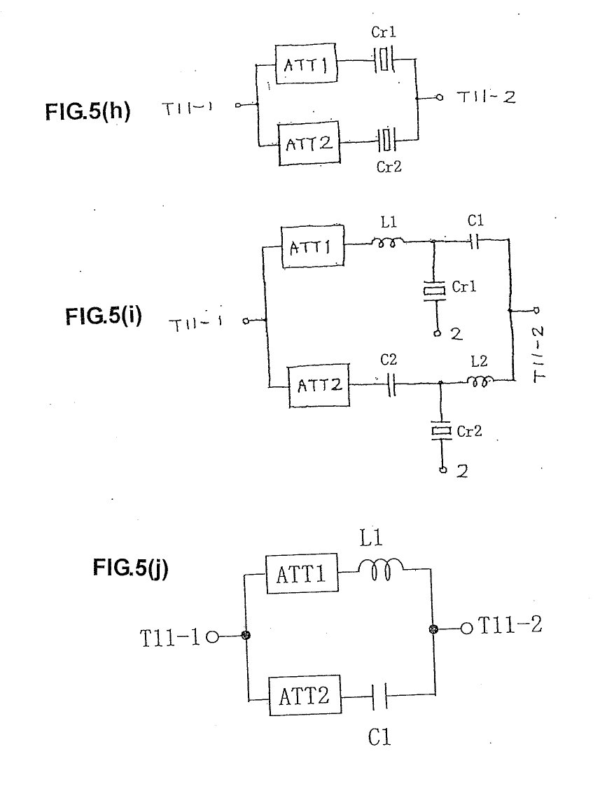

Variants of the resonator circuit 11 of the complex negative feedback frequency selection output circuit 1 shown in FIG. 1 will be described using FIGS. 5(a) to 5(i).

The resonator circuit 11 shown in FIG. 5(a) has a parallel circuit of a series circuit of a coil L and a capacitor C1, and a capacitor C2 between its input terminal T11-1 and its output terminal T11-2. This circuit presents a NULL characteristic in a predetermined frequency band.

The resonator circuit 11 shown in FIG. 5(b) has a parallel circuit of a series circuit of a coil L1 and a capacitor C, and a coil L2 between its input terminal T11-1 and its output terminal T11-2. This circuit presents a NULL characteristic in a predetermined frequency band.

The resonator circuit 11 shown in FIG. 5(c) has a parallel circuit where two series circuits of a coil L1 and a capacitor C1 and of a coil L2 and a capacitor C2 are connected in parallel between its input terminal T11-1 and its output terminal T11-2. This circuit presents a NULL characteristic in a predetermined frequency band.

The resonator circuit 11 shown in FIG. 5(d) is a parallel circuit of a circuit of a coil L1 and a capacitor C1, a coil L2 and a capacitor C2, and a capacitor C3, and a capacitor C4 between its input terminal T11-1 and its output terminal T11-2. This circuit presents a NULL characteristic in a predetermined frequency band.

The resonator circuit 11 shown in FIG. 5(e) has a series circuit of a coil L1 and a capacitor C1 between its input terminal T11-1 and its output terminal T11-2, and a parallel circuit of a series circuit of a coil L2 and a capacitor C2, and a capacitor C3 is connected between the middle point of the series of the coil L1 and the capacitor C1 and the reference terminal 2. This circuit presents a NULL characteristic in a predetermined frequency band.

The resonator circuit 11 shown in FIG. 5(f) has first and second impedance circuits 11, 12 between its input terminal T11-1 and its output terminal T11-2, and a series circuit of a coil L1 and a capacitor C1 is connected between the middle point of the first and second impedance circuits 11, 12 and the reference terminal 2. This circuit presents a NULL characteristic in a predetermined frequency band.

The resonator circuit 11 shown in FIG. 5(g) has a first parallel circuit where a coil L1 and a capacitor C1 are connected in parallel and a second parallel circuit where a coil L2 and a capacitor C2 are connected in parallel between its input terminal T11-1 and its output terminal T11-2, and a series circuit of a coil L3 and a capacitor C3 is connected between the middle point of the first and second parallel circuits and the reference terminal 2, thereby forming a three-terminal circuit. This three-terminal circuit is a configuration example of a T-type band rejecting filter. With this circuit, performance having greatly improved insertion losses and attenuation gradients can be achieved as compared with conventional band pass filters. A filter circuit configured by replacing the capacitors in FIG. 5(g) with variable capacitors to have its band itself variable in frequency can be used as, e.g., a filter for a cognitive radio.

The resonator circuit 11 shown in FIG. 5(h) is a circuit where a first circuit having a first attenuation circuit ATT1 and a first crystal resonator Cr1 cascade-connected and a second circuit having a second attenuation circuit ATT2 and a second crystal resonator Cr2 cascade-connected are connected in parallel between its input terminal T11-1 and its output terminal T11-2. The first and second attenuation circuits ATT1, ATT2 are a circuit which can amplify or attenuate the signal level of the input signal. The first and second crystal resonators are each an element having a predetermined resonance frequency. By changing the attenuation amount of one or both of the first and second attenuation circuits ATT1, ATT2, the anti-resonance frequency can be changed.

In the resonator circuit 11 shown in FIG. 5(i), a first circuit having a first attenuation circuit ATT1, a coil L1, and a capacitor C1 cascade-connected and a second circuit having a second attenuation circuit ATT2, a capacitor C2, and a coil L2 cascade-connected are connected in parallel between its input terminal T11-1 and its output terminal T11-2. A first crystal resonator Cr1 is connected between the middle point of the series of the coil and the capacitor of the first circuit and the reference terminal 2. A second crystal resonator Cr2 is connected between the middle point of the series of the capacitor and the coil of the second circuit and the reference terminal 2. The first and second attenuation circuits ATT1, ATT2 are a circuit which can amplify or attenuate the signal level of the input signal. The first and second crystal resonators are each an element having a predetermined resonance frequency. By changing the attenuation amount of one or both of the first and second attenuation circuits ATT1, ATT2, the anti-resonance frequency can be changed.

The resonator circuit 11 shown in FIG. 5(j) is a circuit where a first circuit having a first attenuation circuit ATT1 and a coil L1 cascade-connected and a second circuit having a second attenuation circuit ATT2 and a capacitor C1 cascade-connected are connected in parallel between its input terminal T11-1 and its output terminal T11-2. The first and second attenuation circuits ATT1, ATT2 are a circuit which can amplify or attenuate the signal level of the input signal. The coil and the capacitor are each a series resonance element having resonance frequencies of zero and the infinite. By changing the attenuation amount of one or both of the first and second attenuation circuits ATT1, ATT2, the anti-resonance frequency can be changed.

The resonator circuit 11 shown in FIG. 1 and the variants shown in FIGS. 5(a) to 5(j) are all an anti-resonant circuit presenting an anti-resonant characteristic in a predetermined frequency band. Hence, these circuits function as a selective relay circuit according to the present invention. That is, not being limited to anti-resonant circuits, a band pass filter that outputs only frequency input signals of a predetermined frequency band or a band rejecting filter also functions as a selective relay circuit according to the present invention. At least one of the values of the circuit elements forming the variant shown in FIGS. 5(a) to 5(j) may be made variable according to an external control signal.

Variants of the compensating circuit 12 of the complex negative feedback frequency selection output circuit 1 shown in FIG. 1 will be described.

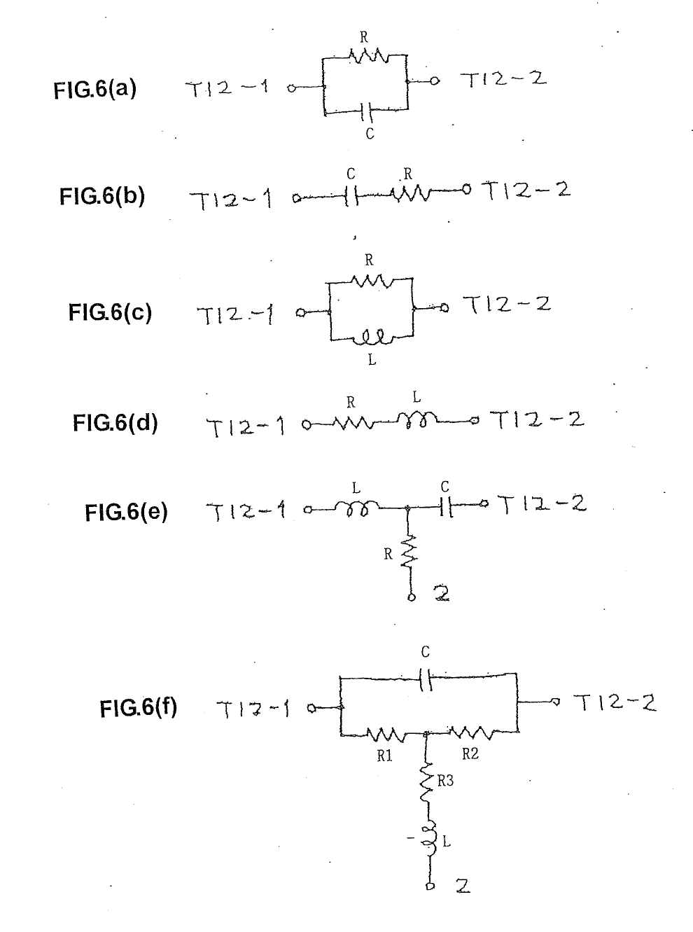

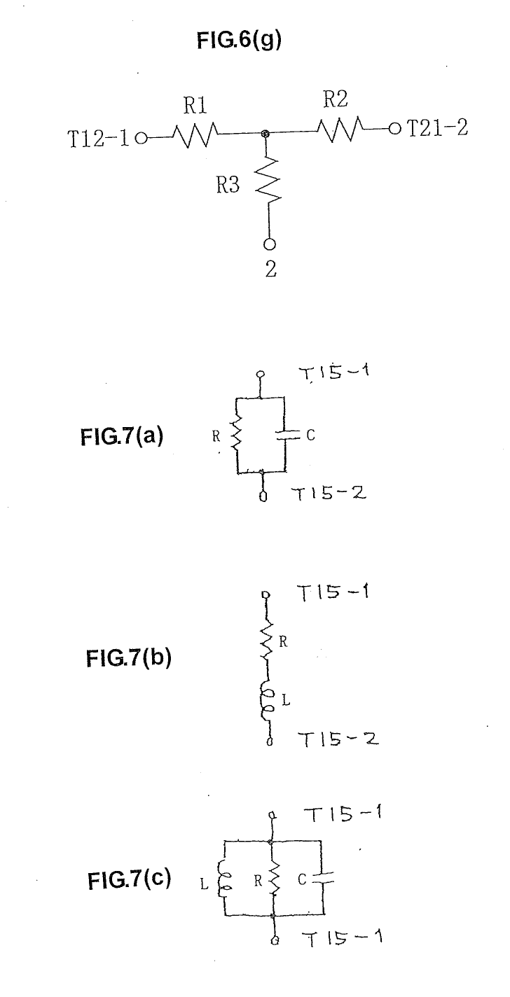

The compensating circuit 12 shown in FIG. 6(a) consists of a resistor R and a capacitor C connected in parallel between its input terminal T12-1 and its output terminal T12-2.

The compensating circuit 12 shown in FIG. 6(b) consists of a resistor R and a capacitor C connected in series between its input terminal T12-1 and its output terminal T12-2.

The compensating circuit 12 shown in FIG. 6(c) consists of a resistor R and a coil L connected in parallel between its input terminal T12-1 and its output terminal T12-2.

The compensating circuit 12 shown in FIG. 6(d) consists of a resistor R and a coil L connected in series between its input terminal T12-1 and its output terminal T12-2.

The compensating circuit 12 shown in FIG. 6(e) consists of a coil L and a capacitor C connected in series between its input terminal T12-1 and its output terminal T12-2, and a resistor R connected between the middle point of the series of the coil L and the capacitor C and the reference terminal 2.

The compensating circuit 12 shown in FIG. 6(f) consists of a capacitor C and two series resistors R1, R2 connected in parallel between its input terminal T12-1 and its output terminal T12-2, and a resistor R3 and a coil L connected in series between the middle point of the two series resistors and the reference terminal 2.

The compensating circuit 12 shown in FIG. 6(g) consists of a resistor R1 and a resistor R2 connected in series between its input terminal T12-1 and its output terminal T12-2, and a resistor R3 connected between the middle point of the resistors R1 and R2 and the reference terminal 2.

In the compensating circuits shown in FIGS. 6(a) to 6(g), reactance elements such as capacitors and coils can be fixed in value or variable according to a predetermined control signal. In the compensating circuits shown in FIGS. 6(a) to 6(g), resistance elements can be fixed in value or variable according to a predetermined control signal. The compensating circuit, not being limited to these variants, can also be formed of capacitance elements and inductance elements that can compensate for unnecessary stray capacitance, residual inductance, and the like in the complex negative feedback frequency selection output circuit 1. Thus, the compensating circuit 12 shown in FIG. 1 and its variants shown in FIGS. 6(a) to 6(g) function as a real number component relay circuit of the present invention.

Variants of the first equivalent load circuit 15 of the complex negative feedback frequency selection output circuit 1 shown in FIG. 1 will be described using FIGS. 7(a) to 7(c).

The first equivalent load circuit shown in FIG. 7(a) consists of a resistor R and a capacitor C connected in parallel between its input terminal T15-1 and its output terminal T15-2.

The first equivalent load circuit shown in FIG. 7(b) consists of a resistor R and a coil L connected in series between its input terminal T15-1 and its output terminal T15-2.

The first equivalent load circuit shown in FIG. 7(c) consists of a resistor R, a coil L, and a capacitor C connected in parallel between its input terminal T15-1 and its output terminal T15-2.

In the first equivalent load circuits shown in FIGS. 7(a) to 7(c), resistance elements and reactance elements such as capacitors and coils can be fixed in value or variable according to a predetermined control signal. The first equivalent load circuit, not being limited to these variants, can also be formed of capacitance elements and inductance elements that can compensate for unnecessary stray capacitance, residual inductance, and the like in the complex negative feedback frequency selection output circuit 1. By changing the reactance component contained in the first equivalent load circuit 15, stable frequency adjustment is possible.

Next, the complex negative feedback frequency selection output circuit 1 will be described from the seven viewpoints of the power distribution negative feedback circuit 23, the resonator circuit 11, the compensating circuit 12, the first equivalent load circuit 15, three current paths (a first in-phase current path 40, a first reverse-phase current path 50, a first negative feedback current path 60), and two loops (a first negative feedback current path loop 70 and a second negative feedback current path loop 80).

The first in-phase current path 40 of the complex negative feedback frequency selection output circuit 1 is a current path from the first input terminal 3 to the in-phase input terminal T11 of the power distribution negative feedback circuit 23 to the in-phase output terminal T31 of the power distribution negative feedback circuit 23 to the terminal T41 to the terminal T51 to the first input terminal T13-1 of the first analog adder circuit 13 to the first virtual analog addition point 17.

The first in-phase current path 40 is characterized in that a signal substantially in phase with the signal applied to the first input terminal 3 flows into the first virtual analog addition point 17 via the first input terminal T13-1 of the first analog adder circuit 13 if the influence of the resonator circuit 11 or the compensating circuit 12 included in this current path is left out. Thus, the first in-phase current path 40 is equivalent to a circuit including a phase shift circuit (or a phase inverting circuit) that performs an even (or zero) number of times of a phase shift of π+α.

The first reverse-phase current path 50 is a current path from the first input terminal 3 to the in-phase input terminal T11 of the power distribution negative feedback circuit 23 to the reverse-phase output terminal T32 of the power distribution negative feedback circuit 23 to the terminal T42 to the terminal T52 to the second input terminal T13-2 of the first analog adder circuit 13 to the first virtual analog addition point 17.

The first reverse-phase current path 50 is characterized in that a signal substantially opposite in phase to the signal applied to the first input terminal 3 flows into the first virtual analog addition point 17 via the second input terminal T13-2 of the first analog adder circuit 13 if the influence of the resonator circuit 11 or the compensating circuit 12 included in this current path is left out. Thus, the first reverse-phase current path 50 is equivalent to a circuit including a phase shift circuit (or a phase inverting circuit) that performs an odd number of times of a phase shift of π+α.

The first negative feedback current path 60 is a current path from the first virtual analog addition point 17 to the output terminal T13-3 of the first analog adder circuit 13 to the terminal T61 to the input terminal T14-1 of the fourth power distribution circuit 14 to the second output terminal T14-3 to the terminal T72 to the reverse-phase input terminal T12. Note that the first negative feedback current path 60 is connected to the first equivalent load circuit 15 connected at one end to the reference terminal 2. If necessary, a predetermined attenuation circuit may be placed together with the first equivalent load circuit 15.

The first negative feedback current path loop 70 of the complex negative feedback frequency selection output circuit 1 is a current path loop from the first virtual analog addition point 17 to the terminal T61 to the terminal T72 to the reverse-phase input terminal T12 to the in-phase output terminal T31 to the terminal T41 to the terminal T51 through the first virtual analog addition point 17.

The first negative feedback current path loop 70 includes part of the first in-phase current path 40 and the first negative feedback current path 60. Suppose that the first negative feedback current path loop 70 is cut at any point such as immediately before the first virtual analog addition point 17 to open the loop. Then as to the phase of the open loop gain, it is equivalent to including a phase shift circuit (or a phase inverting circuit) that performs an odd number of times of a phase shift of π+α if the influence of the resonator circuit 11 or the compensating circuit 12 connected therein is left out. Thus, the first negative feedback current path loop 70 has a signal opposite in phase to the signal applied to the first input terminal 3 flow through the first in-phase current path 40. That is, it presents a negative feedback action. The absolute value of its gain is |μ1|. A circuit having the amplification function to produce this gain may be placed at any point in the loop. The circuit having the amplification function may be placed in a distributed manner or in a lumped manner. The loss in the loop can be incorporated as an attenuation rate.

The second negative feedback current path loop 80 of the complex negative feedback frequency selection output circuit 1 is a current path loop from the first virtual analog addition point 17 to the terminal T61 to the terminal T72 to the reverse-phase input terminal T12 to the reverse-phase output terminal T32 to the terminal T42 to the terminal T52 through the first virtual analog addition point 17.

The second negative feedback current path loop 80 includes part of the first reverse-phase current path 50 and the first negative feedback current path 60. Suppose that the second negative feedback current path loop 80 is cut at any point such as immediately before the first virtual analog addition point 17 to open the loop. Then as to the phase of the open loop gain, it is equivalent to including a phase shift circuit (or a phase inverting circuit) that performs an odd number of times of a phase shift of π+α if the influence of the resonator circuit 11 or the compensating circuit 12 connected therein is left out. Thus, the second negative feedback current path loop 80 has a signal in phase with the signal applied to the first input terminal 3 flow through the first reverse-phase current path 50. That is, it presents a negative feedback action. The absolute value of its gain is |μ2|. A circuit having the amplification function to produce this gain may be placed at any point in the loop. The circuit having the amplification function may be placed in a distributed manner or in a lumped manner. The loss in the loop can be incorporated as an attenuation rate.

Thus, the complex negative feedback frequency selection output circuit 1 can be regarded as a complex negative feedback circuit formed of the first negative feedback current path loop 70 having a reverse-phase current flow through the first in-phase current path 40 at the first virtual analog addition point 17 and the second negative feedback current path loop 80 having a reverse-phase current flow through the first reverse-phase current path 50. In the actual circuit, although a voltage drop and phase inversion may occur in the first negative feedback current path loop 70 and the second negative feedback current path loop 80, such a voltage drop and phase inversion can be suppressed by changing the resistance R3 of the first equivalent load circuit 15 or the gains μ1, μ2 of the two operational amplifying circuits 7, 8.

The arrangement of the resonator circuit 11 and the compensating circuit 12 will be described. Although the embodiment shown in FIG. 1 has a configuration where the resonator circuit 11 is connected in the first in-phase current path 40 and where the compensating circuit 12 is connected in the first reverse-phase current path 50, the present invention is not limited to this. That is, the complex circuit need only be configured such that the resonator circuit 11 is connected in one of the first in-phase current path 40 and the first reverse-phase current path 50 and that the compensating circuit 12 is connected in the other.

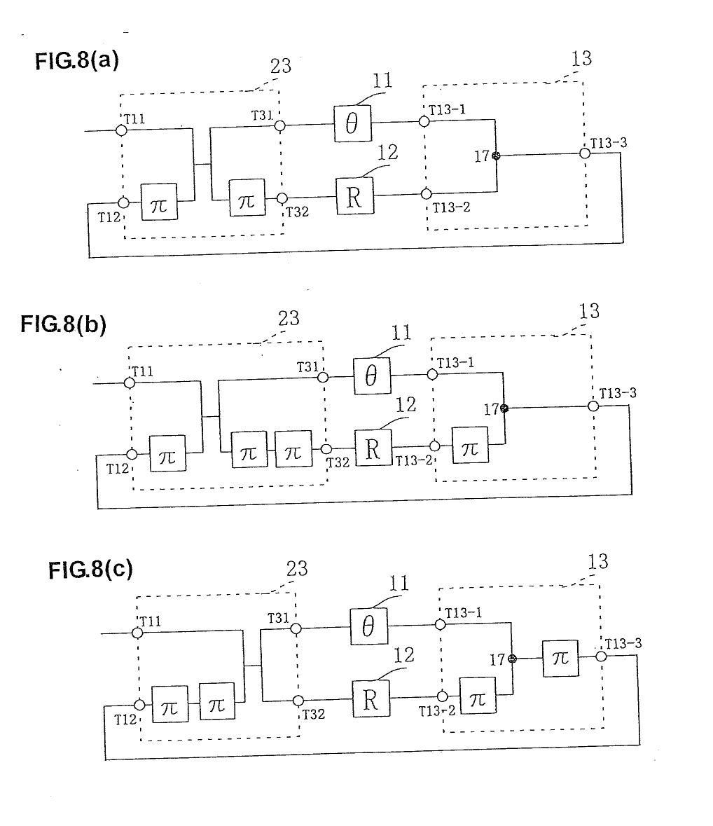

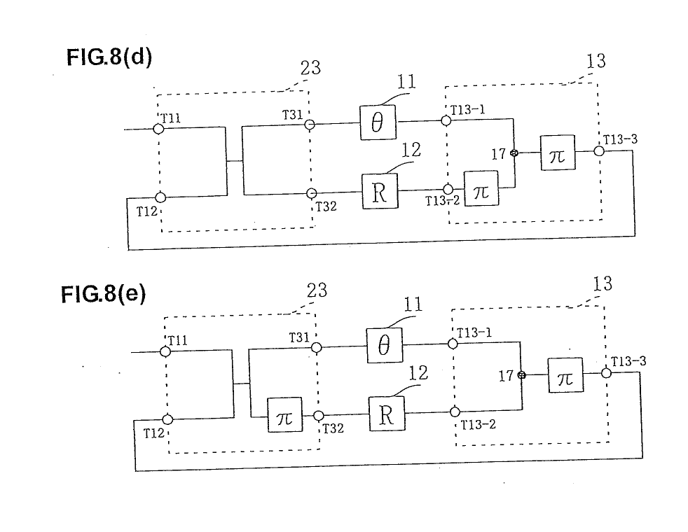

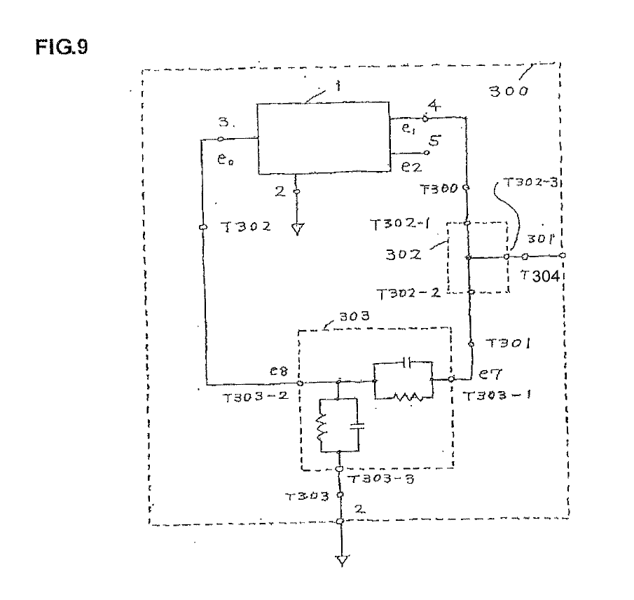

Equivalent circuits of the complex negative feedback frequency selection output circuit 1 according to the present invention will be described using FIGS. 8(a) to 8(e). The reference numerals in FIGS. 8(a) to 8(e) correspond to those in FIG. 1. The n in FIGS. 8(a) to 8(e) indicates an inverting element for inverting the phase, and the θ11 and R12 correspond to the resonator circuit 11 and the compensating circuit 12 in FIG. 1 respectively.

In the equivalent circuit shown in FIG. 8(a), the output signal on the output terminal T31 of the power distribution negative feedback circuit 23 is in phase with the input signal to the input terminal T11, and the output signal on T32 is opposite in phase to the output signal on T31. The signals opposite in phase are output onto the output terminals T31 and T32, are relayed via θ11 and R12 respectively; and are added in the first analog adder circuit 13 to produce their difference signal. The difference signal is fed back to the feedback terminal T12 of the power distribution negative feedback circuit 23. In the power distribution negative feedback circuit 23, the phases at the input terminal T11 and the output terminal T31 are in phase; the phases at the input terminal T11 and the output terminal T32 are opposite; the phases at the feedback terminal T12 and the output terminal T31 are opposite; and the phases at the feedback terminal T12 and the output terminal T32 are in phase.

In the power distribution negative feedback circuit 23 of FIG. 8(b), the two output signals T31 and T32 of the power distribution negative feedback circuit 23 are in phase with each other. The signals in phase are output onto the output terminals T31 and T32, are relayed via θ11 and R12 respectively, and are made opposite in phase to each other and added in the first analog adder circuit 13 to produce their difference signal. The difference signal is fed back to the feedback terminal T12 of the power distribution negative feedback circuit 23. In the power distribution negative feedback circuit 23, the phases at the input terminal T11 and the output terminal T31 are in phase; the phases at the input terminal T11 and the output terminal T32 are in phase; the phases at the feedback terminal T12 and the output terminal T31 are opposite; and the phases at the feedback terminal T12 and the output terminal T32 are opposite.

In the power distribution negative feedback circuit 23 of FIG. 8(c), the two output signals T31 and T32 of the power distribution negative feedback circuit 23 are in phase with each other. The signals in phase are output onto the output terminals T31 and T32, are relayed via θ11 and R12 respectively, and are made opposite in phase to each other and added in the first analog adder circuit 13 to produce their difference signal. The difference signal is inverted in phase in the first analog adder circuit 13 and fed back to the feedback terminal T12 of the power distribution negative feedback circuit 23. In the power distribution negative feedback circuit 23, the phases at the input terminal T11 and the output terminal T31 are in phase; the phases at the input terminal T11 and the output terminal T32 are in phase; the phases at the feedback terminal T12 and the output terminal T31 are in phase; and the phases at the feedback terminal T12 and the output terminal T32 are in phase.

In the power distribution negative feedback circuit 23 of FIG. 8(d), the two output signals T31 and T32 of the power distribution negative feedback circuit 23 are in phase with each other. The signals in phase are output onto the output terminals T31 and T32, are relayed via θ11 and R12 respectively, and are made opposite in phase to each other and added in the first analog adder circuit 13 to produce their difference signal. The difference signal is inverted in phase in the first analog adder circuit 13 and fed back to the feedback terminal T12 of the power distribution negative feedback circuit 23. In the power distribution negative feedback circuit 23, the phases at the input terminal T11 and the output terminal T31 are in phase; the phases at the input terminal T11 and the output terminal T32 are in phase; the phases at the feedback terminal T12 and the output terminal T31 are in phase; and the phases at the feedback terminal T12 and the output terminal T32 are in phase.

In this case, specifically, in the power distribution negative feedback circuit 23, the input terminal T11, the output terminal T31, the feedback terminal T12, and the output terminal T32 should be directly connected to each other, and the circuit of FIG. 4(a) should be used as the first analog adder circuit 13, and the terminal T51 of FIG. 1 should be connected to the terminal T11 of FIG. 4(a), the terminal T52 of FIG. 1 should be to the terminal T12 of FIG. 4(a), and the terminal T61 of FIG. 1 should be to the terminal T32 of FIG. 4(a). Although a signal opposite in phase to the signal output onto the terminal T32 is output onto the terminal T31 of FIG. 4(a), the terminal T31 need not be connected for the purpose in this case.

In the power distribution negative feedback circuit 23 of FIG. 8(e), the two output signals T31 and T32 of the power distribution negative feedback circuit 23 are opposite in phase to each other. The signals opposite in phase are output onto the output terminals T31 and T32, are relayed via θ11 and R12 respectively, and are added in the first analog adder circuit 13 to produce their difference signal. The difference signal is inverted in phase in the first analog adder circuit 13 and fed back to the feedback terminal T12 of the power distribution negative feedback circuit 23. In the power distribution negative feedback circuit 23, the phases at the input terminal T11 and the output terminal T31 are in phase; the phases at the input terminal T11 and the output terminal T32 are opposite; the phases at the feedback terminal T12 and the output terminal T31 are in phase; and the phases at the feedback terminal T12 and the output terminal T32 are opposite.

In the complex negative feedback frequency selection output circuit 1 according to the present invention, a feedback processed signal obtained by performing negative feedback to the input frequency signal on the feedback signal is distributed to two transmission lines, and frequency selection is performed in one of the transmission lines while only the real number component is transmitted over the other transmission line, and the difference signal corresponding to the difference between the two transmitted signals through the transmission lines is used as the feedback signal. With this configuration, a signal produced by suppressing the real number part of the selected frequency component of the input frequency signal is negatively fed back to the input frequency signal, and thus a frequency selection device having a suppressed loss and an enough gain can be obtained.

A loss reduced oscillation circuit 300 that is an embodiment of an oscillation circuit of the present invention using the complex negative feedback frequency selection output circuit 1 shown in FIG. 1 will be described using FIG. 9.

In the complex negative feedback frequency selection output circuit 1 in the loss reduced oscillation circuit 300, when an input signal of a signal level e0 is supplied, an output signal of a signal level e1 is output onto the first output terminal 4. The output signal is supplied to a sixth power distribution circuit 302. A switch circuit to output only one of the output terminal 4 and the output terminal 5 according to an external signal may be inserted between the complex negative feedback frequency selection output circuit 1 and the sixth power distribution circuit 302. Let Gt be a total gain e1/e0 that is the ratio of the signal e1 on the first output terminal 4 to the signal e0 on the first input terminal 3 of the complex negative feedback frequency selection output circuit 1.

The sixth power distribution circuit 302 has an input terminal T302-1 connected to the first output terminal 4 of the complex negative feedback frequency selection output circuit 1, and first and second output terminals T302-2, T302-3. In the sixth power distribution circuit 302, the signal supplied to the input terminal T302-1 is distributed to and output onto the first and second output terminals T302-2, T302-3 with maintaining its signal level and phase. The output signal on the second output terminal T302-3 is output as the oscillation output of the loss reduced oscillation circuit 300 via its output terminal 301.

A first in-phase feedback circuit 303 has an input terminal T303-1 connected to the first output terminal T302-2 of the sixth power distribution circuit 302, and first and second output terminals T303-2, T303-3. In the first in-phase feedback circuit 303, a capacitor and a resistor are connected in parallel between the first and second output terminals T303-2, T303-3, and in addition a capacitor and a resistor are connected in parallel between the middle point of the parallel connection of the capacitor and the resistor and the reference terminal. In the first in-phase feedback circuit 303, the signal supplied to the input terminal T303-1 is attenuated in signal level and shifted in phase and output onto the first output terminal T303-2. Let β1 be a feedback rate e8/e7 that is the ratio of the signal level e8 on the output terminal T303-2 to the signal level e7 on the input terminal T303-1 of the first in-phase feedback circuit 303. The signal level e7 is substantially the same as the signal level e1 from the complex negative feedback frequency selection output circuit 1. The signal level e8 is substantially the same as the signal level e0 supplied to the complex negative feedback frequency selection output circuit 1. The signal output from the output terminal T303-2 of the first in-phase feedback circuit 303 is supplied to the first input terminal 3 via the terminal T302.

In the attenuation processing in the first in-phase feedback circuit 303, the absolute value of the product of the total gain Gt of the complex negative feedback frequency selection output circuit 1 times the feedback rate β1 of the first in-phase feedback circuit 303 is set to be, e.g., greater than 1. In practice, the magnitude of this value should be set at about 2 dB so as to be an excess gain. By this attenuation processing, the oscillation starts and is maintained.

The phase shift processing in the first in-phase feedback circuit 303 is performed by changing an oscillation frequency fL that is the loop frequency of the oscillation loop of the loss reduced oscillation circuit 300 shown in FIG. 9, and the anti-resonance frequency fp of the resonator circuit 11 of the complex negative feedback frequency selection output circuit 1. Further, the phase shift processing is performed such that the frequency at which the transfer admittance of the resonator circuit 11 presents a pole does not coincide with the oscillation frequency.

The purpose of the phase shift processing is to adjust the frequency difference between the oscillation frequency fL that is adjustable by phase shift and the anti-resonance frequency fp of the resonator circuit 11 to obtain a desired resonance sharpness (effective Q factor). Although the oscillation frequency fL is changed by the phase shift, since the resonance sharpness (effective Q factor) changes at the same time, it is difficult to use this phenomenon for oscillation frequency adjustment.

In order to minimize the influence of stray capacitance or residual inductance present in the oscillation loop, the reactance element contained in the first in-phase feedback circuit 303 can be made variable according to an external signal.

With the loss reduced oscillation circuit 300, the sharpness of the oscillation frequency and oscillation output can be improved by adjusting the feedback rate β1 of the first in-phase feedback circuit 303 without changing the circuit constants of the complex negative feedback frequency selection output circuit.

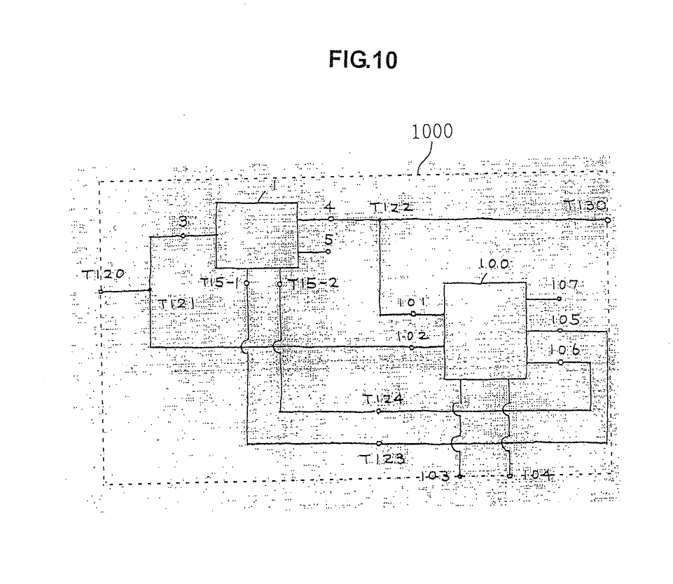

An adjustable complex negative feedback circuit-type frequency selection circuit 1000 that is an embodiment of the present invention will be described using FIG. 10. The adjustable complex negative feedback circuit-type frequency selection circuit 1000 has an input terminal T120. The input terminal T120 is connected to, e.g., a reference signal generator (not shown). The reference signal generator is a device that generates the input frequency signal having its output maintained constant and whose frequency f is variable with, e.g., 10 MHz as the center. The input frequency signal divides at a division terminal T121 and supplied to both the input terminal 3 of the complex negative feedback frequency selection output device 1 and a second detection input terminal 102 of an automatic adjustment circuit 100.

The complex negative feedback frequency selection output device 1 shown in FIG. 10 has the input terminal 3, the two output terminals 4, 5, and terminals T15-1 and T15-2. The input terminal 3 is connected to the input terminal T120. The output terminal 4 is connected via a terminal T122 to an output terminal T130 and a first detection input terminal 101 of the automatic adjustment circuit 100. The complex negative feedback frequency selection output device 1 receives the input frequency signal supplied to the input terminal 3 and outputs a signal in phase with or opposite to the input frequency signal onto the first output terminal 4 and a signal opposite to or in phase with the input frequency signal onto the second output terminal 5. Here, the phase relation between the first output terminal 4 and the second output terminal 5 is as mentioned above in terms of in-phase and reverse-phase. The signal output from the first output terminal 4 is output as a resonance output via the output terminal T130 and is inputted as a detection subject signal to the first detection input terminal 101 of the automatic adjustment circuit 100.

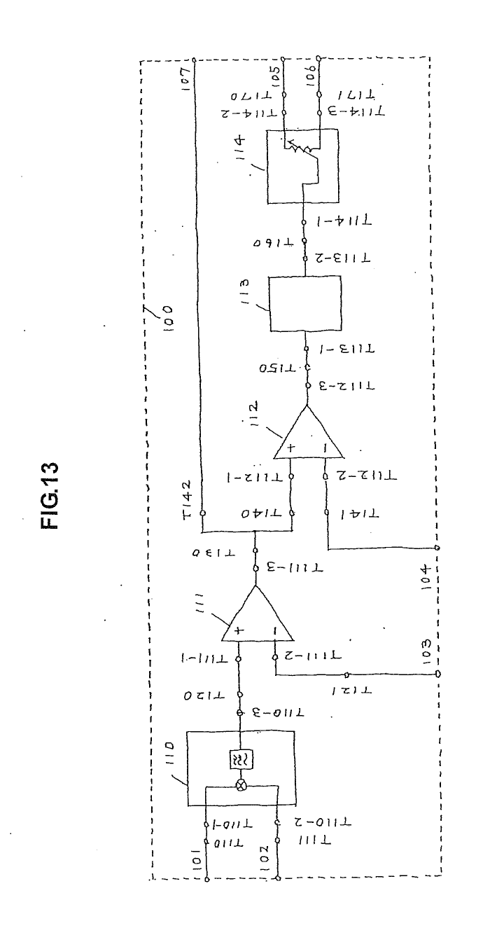

The automatic adjustment circuit 100 shown in FIG. 10 has the first detection input terminal 101, the second detection input terminal 102, an offset compensation input terminal 103, a target value setting signal input terminal 104, a first resistance output terminal 105, a second resistance output terminal 106, and a switching control signal output terminal 107. The first detection input terminal 101 is connected to the output terminal 4 of the complex negative feedback frequency selection output device 1. The second detection input terminal 102 is connected via the division terminal T121 to the input terminal T120. The first and second resistance output terminals 105, 106 are connected to the terminals T15-1 and T15-2 of the complex negative feedback frequency selection output device 1 respectively. The automatic adjustment circuit 100 detects the phases of the input frequency signal and of the in-phase or reverse-phase signal from the complex negative feedback frequency selection output device 1, and based on the phase difference of these signal, can control the complex negative feedback frequency selection output device 1 to output a resonance output having a resonance frequency and resonance sharpness of predetermined target values. This control operation will be described using FIG. 13.

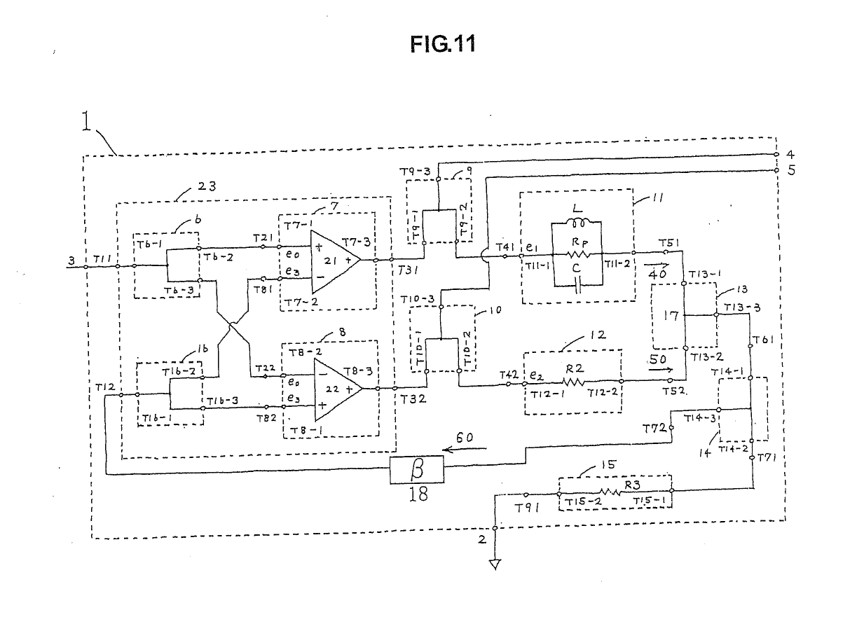

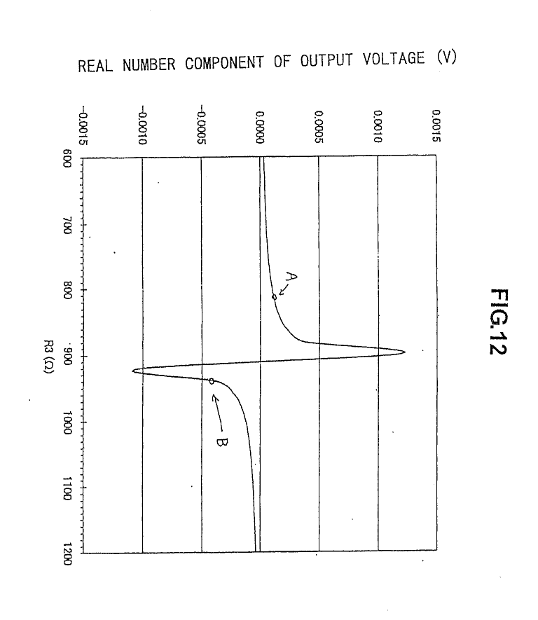

The circuit configuration of the complex negative feedback frequency selection output device 1 of FIG. 10 will be described using FIG. 11.

The power distribution negative feedback circuit 23 of FIG. 11 has an input terminal T11, a feedback terminal T12, an in-phase output terminal T31, a reverse-phase output terminal T32, a first power distribution circuit 6, a first operational amplifying circuit 7, a second power distribution circuit 16, and a second operational amplifying circuit 8.

The input terminal T11 of the power distribution negative feedback circuit 23 is connected to, e.g., a reference signal generator (not shown) via the input terminal 3. The reference signal generator is, for example, a device that generates an input frequency signal having its output maintained constant and whose frequency f is variable with, e.g., 10 MHz as the center. The input frequency signal from the reference signal generator is applied to the input terminal T11 of the power distribution negative feedback circuit 23. A feedback signal from a first analog adder circuit 13 is applied to the feedback terminal T12 of the power distribution negative feedback circuit 23.

The first power distribution circuit 6 of FIG. 11 has an input terminal T6-1 connected to the input terminal T11, and first and second output terminals T6-2, T6-3 connected to the input terminal T6-1. In the first power distribution circuit 6, the input signal inputted to the input terminal T6-1 is distributed to and output onto the first and second output terminals T6-2, T6-3 with maintaining its signal level and phase. Let e0 be the level of the distributed outputted signal.

The fifth power distribution circuit 16 of FIG. 11 has an input terminal T16-1 connected to the feedback terminal T12, and first and second output terminals T16-2, T16-3. In the fifth power distribution circuit 16, the input signal inputted to the input terminal T16-1 is distributed to and output onto the first and second output terminals T16-2, T16-3 with maintaining its signal level and phase. Let e3 be the level of the distributed outputted signal.

The first operational amplifying circuit 7 of FIG. 11 has an in-phase input terminal T7-1, a reverse-phase input terminal T7-2, and a positive-phase output terminal T7-3. The in-phase input terminal T7-1 is connected to the first output terminal T6-2 of the first power distribution circuit 6. The reverse-phase input terminal T7-2 is connected to the first output terminal T16-2 of the fifth power distribution circuit 16.

The first operational amplifying circuit 7 comprises a phase non-inverting circuit that maintains the phase of the input signal supplied to the in-phase input terminal T7-1 with amplifying the level of that input signal with a gain pal, a phase inverting circuit that inverts the phase of the input signal supplied to the reverse-phase input terminal T7-2 with amplifying the level of that input signal with a gain μb1, and an analog adder circuit that adds the output signals in analog of the phase non-inverting circuit and of the phase inverting circuit. Note that the gain μa1 of the phase inverting circuit and the gain μb1 of the phase non-inverting circuit can be set to be either substantially equal or different. The μa1 and the μb1 are taken as the ratio of the signal level e1 supplied to the terminal T11-1 of a resonator circuit 11 to the signal level e0 supplied to the in-phase input terminal T7-1 of the first operational amplifying circuit 7 and taken as the gain μ1 of the first differential input amplifying circuit 7. Note that the gain μ1 of the first differential input amplifying circuit 7 is variable and can be set manually or automatically.

The second differential input amplifying circuit 8 of FIG. 11 has an in-phase input terminal T8-1, a reverse-phase input terminal T8-2, and a positive-phase output terminal T8-3. The in-phase input terminal T8-1 is connected to the second output terminal T16-3 of the second power distribution circuit 16. The reverse-phase input terminal T8-2 is connected to the second output terminal T6-3 of the first power distribution circuit 6.

The second differential input amplifying circuit 8 comprises a phase non-inverting circuit that maintains the phase of the input signal supplied to the in-phase input terminal T8-1 with amplifying the level of that input signal with a gain μa2, a phase inverting circuit that inverts the phase of the input signal supplied to the reverse-phase input terminal T8-2 with amplifying the level of that input signal with a gain μb2, and an analog adder circuit that adds the output signals in analog of the phase non-inverting circuit and of the phase inverting circuit. The gain μa2 of the phase inverting circuit and the gain μb2 of the phase non-inverting circuit can be set to be either substantially equal or different. The μa2 and the μb2 are taken as the ratio of the signal level e2 supplied to the terminal T12-1 of a compensating circuit 12 to a phase inverted signal level from the signal level e0 supplied to the reverse-phase input terminal T8-2 of the second differential input amplifying circuit 8 and taken as the gain μ2 of the second differential input amplifying circuit 8. Note that the gain μ2 of the second differential input amplifying circuit 8 is variable and can be set manually or automatically.

A second power distribution circuit 9 of FIG. 11 has an input terminal T9-1 and first and second output terminals T9-2, T9-3. The input terminal T9-1 is connected to the in-phase output terminal T31 of the power distribution negative feedback circuit 23. The first output terminal T9-2 is connected to the terminal T11-1 of the resonator circuit 11 via the terminal T41. The second output terminal T9-3 is connected to the first output terminal 4. The second power distribution circuit 9 distributes and outputs the input signal inputted to the input terminal T9-1 to and onto the first and second output terminals T9-2, T9-3 with its signal level and phase being maintained.

A third power distribution circuit 10 of FIG. 11 has an input terminal T10-1 and first and second output terminals T10-2, T10-3. The input terminal T10-1 is connected to the reverse-phase output terminal T32 of the power distribution negative feedback circuit 23. The first output terminal T10-2 is connected to the terminal T12-1 of the compensating circuit 12. The second output terminal T10-3 is connected to the second output terminal 5. The third power distribution circuit 10 distributes and outputs the input signal inputted to the input terminal T10-1 to and onto the first and second output terminals T10-2, T10-3 with its signal level and phase being maintained.

In the power distribution negative feedback circuit 23 of FIG. 11, the input frequency signal supplied via the input terminal 3 is inputted via the in-phase input terminal T11, and the feedback signal from the first analog adder circuit 13 is inputted via the reverse-phase input terminal T12. A signal in phase with the input frequency signal is output onto the in-phase output terminal T31, and a signal opposite in phase to the input frequency signal is output onto the reverse-phase output terminal T32.

The resonator circuit 11 of FIG. 11 has terminals T11-1 and T11-2 and is a parallel resonant circuit formed of a coil L, a capacitor C, and a resistor Rp connected in parallel between these terminals. The resonator circuit 11 has a NULL characteristic where its output is attenuated at the anti-resonance frequency fp. Thus, a resonance output attenuated at the band at and around the anti-resonance frequency fp is output via the terminal T11-2 to the first analog adder circuit 13.

The compensating circuit 12 of FIG. 11 has terminals T12-1 and T12-2 and is a pure resistor circuit having a resistor R2 connected between these terminals. In the compensating circuit 12, the input signal supplied to the terminal T12-1 is output via the terminal T12-2 to the first analog adder circuit 13 with being attenuated in signal level through the resistor R2.

The first analog adder circuit 13 of FIG. 11 has a first input terminal T13-1, a second input terminal T13-2, and an output terminal T13-3. The first input terminal T13-1 is connected to the terminal T11-2 of the resonator circuit 11. The second input terminal T13-2 is connected to the terminal T12-2 of the compensating circuit 12. In the first analog adder circuit 13, the signals supplied to the first input terminal T13-1 and the second input terminal T13-2 are added in analog, and the sum is output via the output terminal T13-3 onto the terminal T61. The connection point of the three terminals T13-1, T13-2, T13-3 of the first analog adder circuit 13 is called a “first virtual analog addition point” 17. The level drop between the first virtual analog addition point 17 and the output terminal T13-3 of the first analog adder circuit 13 is negligibly small. Let e3 be the signal level at the first virtual analog addition point 17.

A fourth power distribution circuit 14 has an input terminal T14-1 and first and second output terminals T14-2, T14-3. The input terminal T14-1 is connected via the terminal T61 to the output terminal T13-3 of the first analog adder circuit 13. The first output terminal T14-2 is connected to the input terminal T15-1 of a first equivalent load circuit 15. The second output terminal T14-3 is connected via the terminal T72 to the feedback terminal T12 of the power distribution negative feedback circuit 23. In the fourth power distribution circuit 14, the signal supplied to the input terminal T14-1 is output onto the first and second output terminals T14-2 and T14-3.

The first equivalent load circuit 15 of FIG. 11 is a potential adjusting circuit included in a circuit loop from the input terminal 3 to the feedback terminal T12 and is a pure resistor circuit having an input terminal T15-1, an output terminal T15-2, and a resistor R3 connected between these terminals. The input terminal T15-1 is connected to the first output terminal T14-2 of the fourth power distribution circuit 14. The output terminal T15-2 is connected to the reference terminal 2. The reference terminal 2 is connected to reference potential such as ground potential, power supply potential, or predetermined intermediate potential. By changing the resistance of the pure resistor of the first equivalent load circuit 15 of FIG. 11, the loop gain of the circuit loop from the input terminal 3 to the feedback terminal T12 can be adjusted.

A loop gain adjusting circuit 18 shown in FIG. 11 is a variable amplifier or a variable attenuator inserted in the negative feedback current path 60. The gain or the attenuation rate of the loop gain adjusting circuit 18 is variable and can be set manually or automatically so as to adjust the loop gain of the circuit loop from the input terminal 3 to the feedback terminal T12.

In another embodiment, the loop gain adjusting circuit 18 is also inserted in another circuit loop from the input terminal 3 to the feedback terminal T12 of the complex negative feedback frequency selection output device 1. For example, where inserted in the power distribution negative feedback circuit 23, the adjustment of the loop gain can be performed by making the resistor Re, e.g., shown in FIG. 4(a), the resistors Re1 and/or Re2, e.g., shown in FIG. 4(b), or the resistor Rc, e.g., in FIG. 4(c) be a variable resistor and adjusting the value of the variable resistance manually or automatically. In the compensating circuit 12, the adjustment of the loop gain can be performed by making the resistor R2 of the compensating circuit 12 in FIG. 11 be a variable resistor and adjusting the value of the variable resistance manually or automatically. None of the loop gain adjustments in FIGS. 4(d), 4(e), 4(f) are continuous adjustment, and those loop gains may be adjusted stepwise. That is, in FIG. 4(d), a plurality of taps may be provided in the primary winding or the secondary winding of the transformer T, and the plurality of taps may be switched stepwise. In FIG. 4(e), a plurality of λ/2 micro-strip resonant circuits b and a plurality of λ/2 micro-strip resonant circuits e which are changed stepwise in, e.g., characteristic impedance may be provided, and the plurality of λ/2 micro-strip resonant circuits b and the plurality of λ/2 micro-strip resonant circuits e may be switched stepwise. Also in FIG. 4(f), likewise the characteristic impedance may be changed stepwise, and hence description thereof is omitted.

The automatic adjustment circuit 100 of FIG. 10 will be described using FIG. 13. As shown in FIG. 13, the automatic adjustment circuit 100 has the first detection input terminal 101, the second detection input terminal 102, the offset compensation input terminal 103, the target value setting signal input terminal 104, the first resistance output terminal 105, the second resistance output terminal 106, and the switching control signal output terminal 107.

The first detection input terminal 101 shown in FIG. 13 is connected to the output terminal 4 of the complex negative feedback frequency selection output device 1 shown in FIG. 10, and the second detection input terminal 102 is connected to the input terminal T120 of the automatically adjusted complex negative feedback circuit-type frequency selection circuit 1000 shown in FIG. 10. The output signal from the first output terminal 4 of the complex negative feedback frequency selection output device 1 is supplied to the first detection input terminal 101, and the input frequency signal via the input terminal T120 of the automatically adjusted complex negative feedback circuit-type frequency selection circuit 1000 is supplied to the second detection input terminal 102.

A phase detecting circuit 110 performs phase detection on two signals that are a detection subject signal supplied from the first detection input terminal 101 via the terminal T110 to the terminal T110-1 and a detection reference signal supplied from the second detection input terminal 102 via the terminal T111 to the terminal T110-2 and outputs a detection output onto the terminal T120 via the detection output terminal T110-3.

A first analog signal adder circuit 111 shown in FIG. 13 is an analog adder circuit having a first input terminal T111-1, a second input terminal T111-2, and an output terminal T111-3. The first input terminal T111-1 is connected via the terminal T120 to the detection output terminal T110-3 of the phase detecting circuit 110. The second input terminal T111-2 is connected via the terminal T121 to the offset compensation input terminal 103. A predetermined signal is supplied as an offset compensation signal to the offset compensation input terminal 103. The first analog signal adder circuit 111 adds in analog the signal supplied to the first input terminal T111-1 and the offset compensation signal. The first analog signal adder circuit 111 outputs the sum signal obtained by the analog addition via the output terminal T111-3.

The output signal via the output terminal T111-3 of the first analog signal adder circuit 111 is supplied via the terminals T130 and T142 to the switching control signal output terminal 107 and via the terminals T130 and T140 to the positive input terminal T112-1 of a second analog signal adder circuit 112.

The second analog signal adder circuit 112 shown in FIG. 13 has two input terminals that are the positive input terminal T112-1 and a negative input terminal T112-2, and an output terminal T112-3. The positive input terminal T112-1 is connected via the terminals T140 and T130 to the output terminal T111-3 of the first analog signal adder circuit 111. The negative input terminal T112-2 is connected via the terminal T141 to the target value setting signal input terminal 104. A predetermined signal is supplied as a target value setting signal to the target value setting signal input terminal 104. The second analog signal adder circuit 112 adds in analog the signal supplied to the positive input terminal T112-1 and the target value setting signal supplied to the negative input terminal T112-2 and outputs the sum signal obtained by the analog addition via the output terminal T112-3. The output signal from the output terminal T112-3 of the second analog signal adder circuit 112 is supplied to an integration circuit 113 via the terminal T150.

The integration circuit 113 shown in FIG. 13 has a first input terminal T113-1 and an output terminal T113-2. The first input terminal T113-1 is connected to the output terminal T112-3 of the second analog signal adder circuit 112, and the output terminal T113-2 is connected to an electronically controlled resistor 114. The integration circuit 113 integrates in analog the signal supplied to the first input terminal T113-1 and outputs the obtained integration result via the output terminal T113-2. The integration result is supplied to the input terminal T114-1 of the electronically controlled resistor 114.

The electronically controlled resistor 114 shown in FIG. 13 is a circuit having an input terminal T114-1, a first resistance output terminal T114-2, a second resistance output terminal T114-3, and an electronically controlled resistor 114. The input terminal T114-1 is connected via the terminal T160 to the output terminal T113-2 of the integration circuit 113. The first resistance output terminal T114-2 is connected via the terminal T170 to the terminal T105. The second resistance output terminal T114-3 is connected via the terminal T171 to the terminal T106. The electronically controlled resistor 114 is connected between the first resistance output terminal T114-2 and the second resistance output terminal T114-3. The electronically controlled resistor 114 can adjust the resistance of the first equivalent load circuit 15 shown in FIG. 11.

The first and second resistance output terminal T114-2, T114-3 are respectively connected via the terminals T105, T106 to the terminals T15-1, T15-2 of the automatically adjusted complex negative feedback circuit-type frequency selection circuit 1000 of FIG. 10.

Next, the operation of the automatic adjustment circuit 100 shown in FIG. 13 will be described. The signal supplied to the first detection input terminal 101 of the automatic adjustment circuit 100 is referred to as a “detection subject signal”. The detection subject signal corresponds to the signal supplied via the first output terminal 4 in FIG. 10 or 11, and its signal level is proportional to e1. The signal supplied to the second detection input terminal 102 of the automatic adjustment circuit 100 is referred to as a “detection reference signal”. The detection reference signal corresponds to the signal supplied via the first input terminal 3 in FIG. 10 or 11, and its signal level is proportional to e0.

The phase detecting circuit 110 of the automatic adjustment circuit 100 detects the phase of the detection subject signal supplied to the first detection input terminal T110-1 with the phase of the detection reference signal supplied to the second detection input terminal T110-2 as a reference. Further, the phase detecting circuit 110 of the automatic adjustment circuit 100 extracts the phase component identical to the phase of the detection reference signal out of the phase components of the detection subject signal. The direct current signal obtained by the phase detection and phase detecting is output as a detection output signal onto the terminal T120 via the output terminal T110-3.

The first analog adder circuit 111 adds in analog the detection output signal and the offset compensation signal supplied to the negative input terminal T111-2 via the terminal 121 from the offset compensation input terminal 103. The first analog adder circuit 111 outputs the direct current signal corresponding to the analog added signal onto the terminal T130 via the output terminal T111-3. The output signal obtained from the first analog adder circuit 111 is referred to as a “compensated in-phase signal”. The compensated in-phase signal passing through the terminal 130 is an important signal indicating the operation state of the complex negative feedback frequency selection output device 1.

The offset compensation signal supplied to the offset compensation input terminal 103 of the first analog adder circuit 111 will be described. The offset compensation signal is necessary for compensation because the signal (signal level e1) from the first output terminal is used as the detection subject signal. This compensation signal is a direct current signal related to the first term μl/(μ1+1) on the right side of the equation (1). By performing this compensation, when some of y3, y2, μ1, μ2 are changed, the plus-minus inversion of the sign of the denominator of the term containing yr on the right side of the equation (1) and the plus-minus inversion of the sign of the detected signal intended can be made to coincide in timing. The degree of disparity in timing becomes noticeable especially when the ratio e1/e0 is set to be relatively small. Hence, this compensation produces an important effect. Further, this disparity phenomenon also occurs when μ1=μ2.

The second analog signal adder circuit 112 subtracts in analog the compensated in-phase signal supplied to the positive input terminal T112-1 from the target value setting signal supplied to the negative input terminal T112-2. The second analog signal adder circuit 112 outputs the direct current signal (hereinafter called an error signal) corresponding to the analog subtracted signal onto the terminal T150 via the output terminal T112-3.

The target value setting signal supplied to the negative input terminal T112-2 of the second analog signal adder circuit 112 will be described. The target value setting signal is associated with a loss reduction multiple p by a relation calculated from the equation (1). That is, by setting the target value setting signal, a target value for the loss reduction multiple p can be set.

The integration circuit 113 integrates the error signal supplied to the input terminal T113-1 and outputs the direct current signal (hereinafter called an integrated signal) corresponding to the obtained integrating result via the output terminal T113-2 onto the terminal T160. The loop gain, loop filter, blind range, and the like can be set arbitrarily in the integration circuit 113.

The electronically controlled resistor 114 generates a “resistor” having the resistance associated with the integrated signal between the first output terminal T114-1 and the second output terminal T114-2.

The resistor occurring between the first resistance output terminal 105 and the second resistance output terminal 106 is used as all or part of the resistance R3 of the equivalent load circuit 15 of the complex negative feedback frequency selection output device 1 shown in FIG. 10.

The further operation of the adjustable complex negative feedback circuit-type frequency selection circuit 1000 shown in FIG. 10 will be described using FIG. 12. Here, since this is a description of the operation principle, description will be made with the influence of the first term on the right side of the equation (1) being neglected for being small and with μ1/(μ1+1) being equal to 1.

The voltage ratio e1/e0 shown in the equation (1) can be expressed by the frequency characteristics of the real number component (in-phase component) and the imaginary number component (π/2 shift component) of the voltage ratio e1/e0.

In the present invention, attention will be focused on the frequency characteristic of the real number component of the voltage ratio e1/e0. The frequency characteristic of the real number component of the voltage ratio e1/e0 has the features as follows.

First, the real number component of the voltage ratio e1/e0 is an even function against frequency and when the frequency changes, the real number component of the voltage ratio e1/e0 does not become zero, that is, does not cross the horizontal axis.

Second, the real number component of the voltage ratio e1/e0 can take on a negative, zero, or positive value depending on the combination range of two gains μ1, μ2, and y2, y3 that are circuit constants in FIG. 1, that is, the parameters of the equation (1).

Since this phenomenon does not depend on the frequency, FIG. 12 shows a relation between the real number component of the voltage ratio e1/e0 and y3 at the anti-resonance frequency fp of the resonator circuit 11. Here, the other parameters, two gains μ1, μ2, and y2, are fixed. The vertical axis represents the real number component of the voltage ratio e1/e0, and the horizontal axis represents the resistance R3 that is the inverse of y3. The setting conditions for the parameters are as shown in table 1.

Next, the relation shown in FIG. 12 existing between the real number component of the output voltage on the vertical axis and the resistance R3 of the equivalent load circuit 15 on the horizontal axis means that the operation point of the complex negative feedback frequency selection output device 1 in FIG. 1 can be set at point A by adjusting the parameter R3. Since the value on the vertical axis for this point A is an amount directly related to the loss reduction multiple p through the equation (1), it is a practically important set amount.

The third analog adder circuit 112 subtracts the target value setting signal corresponding to the value on the vertical axis for the point A in FIG. 12 and inputted to the target value setting signal input terminal 104 of FIG. 10 from the output signal of the second analog adder circuit 111. This difference (error signal) is output via its output terminal. This error signal is integrated by the integration circuit 113, and the output signal is supplied to the input terminal of the electronically controlled resistor 114. The electronically controlled resistor 114 outputs the resistance value corresponding to the signal supplied from the integration circuit 113. This value corresponds to a value on the horizontal axis of FIG. 12. In this series of operations, the circuit of FIG. 10 operates such that the error signal becomes zero. This is the same as in the conventional feedback control technique. As such, the target value corresponding to the value on the vertical axis for the point A in FIG. 12 and inputted to the target value setting signal input terminal 104 is satisfied.

Next, the sweeping direction of ramp voltage in the feedback control may be specified. This is because the real number component of the voltage ratio e1/e0 on the vertical axis changes from a positive value through zero to a negative value when the resistance R3 on the horizontal axis increases through a boundary of 910Ω.

The integration circuit 113 of FIG. 13 should sweep the ramp voltage from the side where the resistance R3 is lower when the target value is set at a positive value as indicated by the point A in FIG. 12, and conversely from the side where the resistance R3 is higher when the target value is set at a negative value as indicated by the point B in FIG. 12, thereby avoiding the value on the vertical axis of FIG. 12 from becoming zero.

The adjustable complex negative feedback circuit-type frequency selection circuit 1000 shown in FIG. 10 has the following advantages as well as those of the complex negative feedback frequency selection output circuit shown in FIG. 1. In the complex negative feedback frequency selection output circuit shown in FIG. 1, the maximum value and FWHM of the peak voltage at the resonance frequency as shown in FIG. 2 and the phase of the output signal with respect to that of the input signal as shown in FIG. 3 are adjustable with the resistance of the compensating circuit 12, the resistance of the first equivalent load circuit 15, the gains of the first differential input amplifying circuit 7 and the second differential input amplifying circuit 8 of the power distribution negative feedback circuit 23 as variable parameters. However, when the physical constants of elements contained in the complex negative feedback frequency selection output circuit change due to, e.g., a change in the environment such as a change in temperature, the complex negative feedback frequency selection output circuit shown in FIG. 1 operates such that the peak voltage and the phase at the resonance frequency are maintained at desired target set values, following a change in the environment. Thus, the adjustable complex negative feedback circuit-type frequency selection circuit shown in FIG. 10 can maintain a desired output set as a target correspondingly to the external environment.

As to the signal supplied from the terminal T122 to the terminal T101 and the signal supplied from the terminal T121 to the terminal T102 in FIG. 10, two signals keeping their amplitude ratio and phase difference with respect to the two signals from the terminal T122 and from the terminal T121, which signals are obtained by a beat down technique or the like using the same local oscillation frequency, can be supplied to the terminal T101 and the terminal T102 respectively.

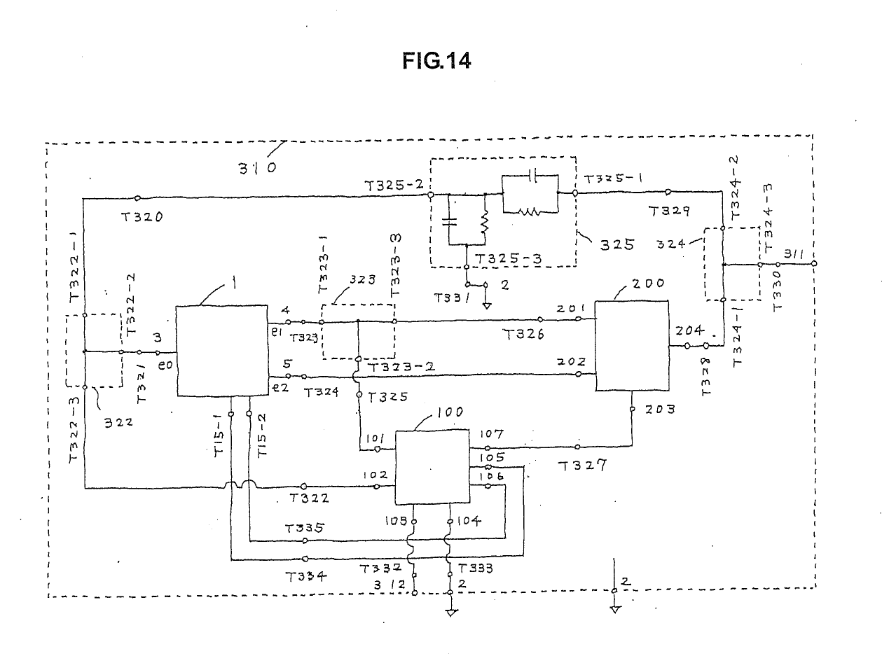

The adjustable complex negative feedback circuit-type frequency selection circuit 1000 shown in FIG. 10 and an oscillation circuit 310 using the same will be described using FIG. 14.

A seventh power distribution circuit 322 shown in FIG. 14 has an input terminal T322-1, and first and second output terminals T322-2, T322-3. The input terminal T322-1 is connected to the output terminal T325-2 of a second in-phase feedback circuit 325. The first output terminal T322-2 is connected to the input terminal 3 of the complex negative feedback frequency selection output device 1. The second output terminal T322-3 is connected to the second detection input terminal 102 of the automatic adjustment circuit 100. The seventh power distribution circuit 322 distributes and outputs an oscillation signal supplied to the input terminal T322-1 to and onto the terminals T321 and T322 via the first and second output terminals T322-2, T322-3 respectively.

In the complex negative feedback frequency selection output device 1 shown in FIG. 14, the input terminal 3 is connected to the first output terminal T322-2 of the seventh power distribution circuit 322. The first output terminal 4 is connected to the input terminal T323-1 of an eighth power distribution circuit 323. The second output terminal 5 is connected to the second input terminal 202 of an output switching circuit 200. The terminals T15-1 and T15-2 are connected to the first resistance output terminal 105 and the second resistance output terminal 106 of the automatic adjustment circuit 100 respectively.

The eighth power distribution circuit 323 shown in FIG. 14 has an input terminal T323-1, and first and second output terminals T323-2, T323-3. The input terminal T323-1 is connected to the first output terminal 4 of the complex negative feedback frequency selection output device 1. The first output terminal T323-2 is connected to the first detection input terminal 101 of the automatic adjustment circuit 100. The second output terminal T323-3 is connected to the first input terminal 201 of the output switching circuit 200. The eighth power distribution circuit 323 distributes and outputs the signal supplied to the input terminal T323-1 to the first detection input terminal 101 and the first input terminal 201 via the first and second output terminals T323-2, T323-3 respectively.

In the automatic adjustment circuit 100 shown in FIG. 14, the first detection input terminal 101 is connected to the first output terminal T323-2 of the eighth power distribution circuit 323, and the second detection input terminal 102 is connected to the second output terminal T322-3 of the seventh power distribution circuit 322. The offset compensation input terminal 103 is connected to the offset compensation signal input terminal 312. The target value setting signal input terminal 104 is connected to the reference terminal 2. The switching control signal output terminal 107 is connected to the switching control signal input terminal 203 of the output switching circuit 200. The first resistance output terminal 105 is connected to the terminal T15-1 of the complex negative feedback frequency selection output device 1. The second resistance output terminal 106 is connected to the terminal T15-2 of the complex negative feedback frequency selection output device 1.

In the output switching circuit 200 shown in FIG. 14, the first input terminal 201 is connected to the second output terminal T323-3 of the eighth power distribution circuit via T326. The second input terminal 202 is connected to the second output terminal 5 of the complex negative feedback frequency selection output device 1 via T324. The switching control signal input terminal 203 is connected to the switching control signal output terminal 107 of the automatic adjustment circuit 100 via T327. The third output terminal 204 is connected to the first input terminal T324-1 of a ninth power distribution circuit 324 via the terminal T328.

The ninth power distribution circuit 324 shown in FIG. 14 has an input terminal T324-1, and first and second output terminals T324-2, T324-3. The input terminal T324-1 is connected to the third output terminal 204 of the output switching circuit 200 via the terminal T328. The first output terminal T324-2 is connected to the input terminal T325-1 of the second in-phase feedback circuit 325 via the terminal T329. The second output terminal T324-3 is connected to the output terminal 311 via the terminal T330. The ninth power distribution circuit 324 distributes and outputs the signal supplied to the input terminal T324-1 to the input terminal T325-1 of the second in-phase feedback circuit 325 and the output terminal 311 via the first and second output terminals T324-2, T324-3 respectively.

The second in-phase feedback circuit 325 shown in FIG. 14 has the input terminal T325-1, the output terminal T325-2, the terminal T325-3, a capacitor and a resistor connected in parallel between the input terminal T325-1 and the output terminal T325-2, and a capacitor and a resistor connected in parallel between the terminal T325-2 and the terminal T325-3. The terminal T325-3 is connected to the reference terminal 2 via the terminal T331.

The second in-phase feedback circuit 325 attenuates in signal level and shifts in phase the signal supplied to the input terminal T325-1 and outputs onto the output terminal T325-2. Let feedback rate 131 be the ratio e8/e7 of a signal level e8 on the output terminal T325-2 of the second in-phase feedback circuit 325 to a signal level e7 on the input terminal T325-1. The signal level e7 is substantially the same as the signal level e1 from the complex negative feedback frequency selection output circuit 1. The signal level e8 is substantially the same as the signal level e0 supplied to the complex negative feedback frequency selection output circuit 1. The signal outputted via the output terminal T325-2 of the second in-phase feedback circuit 325 is supplied to the first input terminal 3 via the terminal T320.

In the attenuation processing in the second in-phase feedback circuit 325, the absolute value of the product of the total gain Gt of the complex negative feedback frequency selection output circuit 1 times the feedback rate β1 of the second in-phase feedback circuit 325 is set to be, e.g., greater than 1. In practice, the magnitude of this value should be set at about 2 dB so as to be an excess gain. By this attenuation processing, the oscillation starts and is maintained.

The phase shift processing in the second in-phase feedback circuit 325 is performed by changing an oscillation frequency fL that is the loop frequency of the oscillation loop of an oscillation circuit 310 shown in FIG. 14, and the anti-resonance frequency fp of the resonator circuit 11 of the complex negative feedback frequency selection output circuit 1. Further, the phase shift processing is performed such that the frequency at which the transfer admittance of the resonator circuit 11 presents a pole does not coincide with the oscillation frequency. In order to minimize the influence of stray capacitance or residual inductance present in the oscillation loop, the reactance element contained in the second in-phase feedback circuit 325 can be made variable according to an external signal.

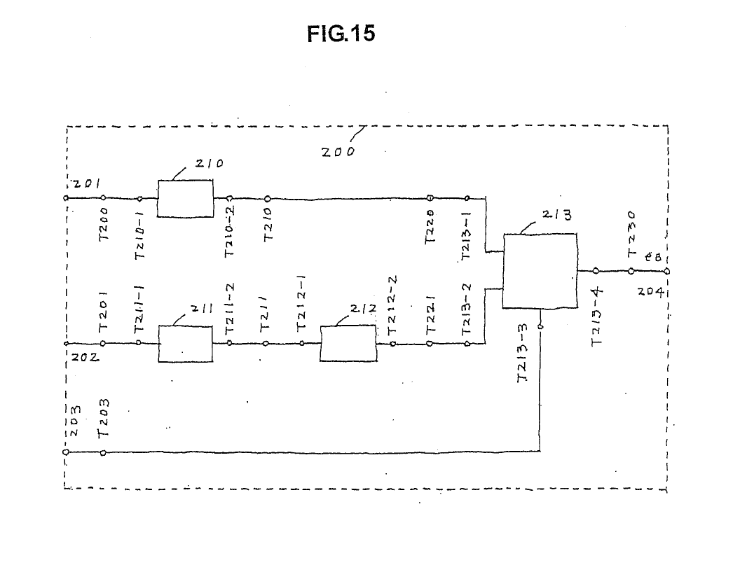

The circuit configuration of the output switching circuit 200 shown in FIG. 14 will be described using FIG. 15. The output switching circuit 200 has a first input terminal 201, a second input terminal 202, a switching control signal input terminal 203, and a third output terminal 204. The first input terminal 201 is connected to the first output terminal 4 of the complex negative feedback frequency selection output device 1 of FIG. 14. The second input terminal 202 is connected to the second output terminal 5 of the complex negative feedback frequency selection output device 1 of FIG. 14. The switching control signal input terminal 203 is connected to the switching control signal output terminal 107 of the automatic adjustment circuit 100. The third output terminal 204 is connected to the terminal T324-1 of the ninth power distribution circuit 324.

A first amplitude phase compensation circuit 210 shown in FIG. 15 has an input terminal T210-1 connected via the terminal T200 to the first input terminal 201 and an output terminal T210-2 connected to the first input terminal T213-1 of an output switching switch 213. The first amplitude phase compensation circuit 210 performs compensation on the amplitude and phase of the signal supplied to the input terminal T210-1 and outputs the compensated signal via the output terminal T210-2 onto the terminal T210.

A second amplitude phase compensation circuit 211 shown in FIG. 15 has an input terminal T211-1 connected via the terminal T201 to the second input terminal 202 and an output terminal T211-2 connected to the input terminal T212-1 of a first phase inverting circuit 212 via the terminal T211. The first amplitude phase compensation circuit 210 performs compensation on the amplitude and phase of the signal supplied to the input terminal T210-1 and outputs the compensated signal via the output terminal T210-2 onto the terminal T210.

The first phase inverting circuit 212 shown in FIG. 15 has an input terminal T212-1 and an output terminal T212-2 connected to the second input terminal T213-2 of the output switching switch 213 via the terminal T221. The first phase inverting circuit 212 performs a phase shift of π+α on the signal supplied to the input terminal T212-1 from the output terminal T211-2 of the second amplitude phase compensation circuit 211 and outputs the phase-shifted signal via the output terminal T212-2 onto the terminal T221.

The output switching switch 213 shown in FIG. 15 has a first input terminal T213-1, a second input terminal T213-2, a control input terminal T213-3, and an output terminal T213-4. The control input terminal T213-3 is connected to the switching control signal input terminal 203 via T203 and the switching control signal input terminal 203 is connected to the switching control signal output terminal 107 of the automatic adjustment circuit 100. The output switching switch 213 selects one of the signals supplied to the first input terminal T213-1 and the second input terminal T213-2 according to the switching control signal supplied to the control input terminal T213-3 from the switching control signal output terminal 107 of the automatic adjustment circuit 100 and outputs the one via the output terminal T213-4. The output terminal T213-4 of the output switching switch 213 is connected via the terminal T230 to the third output terminal 204. The third output terminal 204 is connected to the terminal T324-1 of the ninth power distribution circuit 324 of FIG. 14.

The operation of the output switching circuit 200 shown in FIG. 15 will be described in detail. A signal from the first output terminal 4 of the complex negative feedback frequency selection output device 1 of FIG. 11 is supplied to the second input terminal 201 of the output switching circuit 200. A signal from the second output terminal 5 of the complex negative feedback frequency selection output device 1 of FIG. 11 is supplied to the second input terminal 202 of the output switching circuit 200.

The first amplitude phase compensation circuit 210 performs amplitude-and-phase compensation by a “first compensation coefficient” on the signal supplied to the input terminal T210-1 via the terminal T200 from the second input terminal 201 and outputs via the output terminal T210-2 onto the terminal T210.

The second amplitude phase compensation circuit 211 performs amplitude-and-phase compensation by a “second compensation coefficient” on the signal supplied to the input terminal T211-1 via the terminal T201 from the second input terminal 202 and outputs via the output terminal T211-2 onto the terminal T211.

The “first compensation coefficient” can be determined, for example, taking into account the ratio of its value when μ1 is set at the infinite to the one when set at an actual design value as to the term containing two μ1's in the equation (1) denoting the signal level (e1) on the first output terminal 4 of FIG. 11. By this operation, the signal level (e1) on the first output terminal 4 of FIG. 11 is standardized.

In order to determine the “second compensation coefficient”, by replacing μ1 with −μ2 and μ2 with −μ1 in the equation (1), the signal level (e2) on the second output terminal 5 of FIG. 11 is denoted. The coefficient can be determined taking into account the ratio of its value when μ2 is set at the infinite to the one when set at an actual design value as to the term containing two μ2's. By this operation, the signal level (e2) on the second output terminal 5 of FIG. 11 is standardized.

By these standardizing operations, when switching between the signal inputted to the second input terminal 201 and the signal inputted to the third input terminal 202, continuity is provided for the output signal from the third output terminal 204. μ1 and μ2 usually have a small imaginary number component.

The first phase inverting circuit 212 performs a phase shift of π+α on the signal supplied to the input terminal T212-1 from the output terminal T211-2 of the second amplitude phase compensation circuit 211 via the terminal T211 and outputs via the output terminal T212-2 onto the terminal T221. α is usually a small value.

The output switching switch 213 selects one of the signal (signal level e4) supplied to the first input terminal T213-1 and the signal (signal level e5) supplied to the second input terminal T213-2 according to the switching control signal supplied to the control input terminal T213-3 and outputs the one via the output terminal T213-4 onto the terminal T230. The signal output via the output terminal T213-4 of the output switching switch 213 is output onto the third output terminal 204 via the terminal T230. In this case, a signal in phase with the signal applied to the first input terminal 3 of the complex negative feedback frequency selection output device 1 of FIG. 11 is always output onto the third output terminal 204.

Next, two modified embodiments of the output switching circuit 200 shown in FIG. 15 will be described. First, in the output switching circuit 200 shown in FIG. 15, the direct connection between the terminal T210 and the terminal T220 is cut off, and the first phase inverting circuit 212 is removed from between the terminal T211 and the terminal T221 and then placed between the terminal T210 and the terminal T220, and the terminal T211 and the terminal T221 are directly connected. In this case, a signal shifted by π from, i.e. opposite in phase to, the signal applied to the first input terminal 3 of the complex negative feedback frequency selection output device 1 of FIG. 11 is always output onto the output terminal 204.

Second, the circuit outputting a signal in phase with the signal applied to the first input terminal 3 shown in FIG. 15 and the circuit outputting a signal opposite in phase to the signal applied to the first input terminal 3 described in the above modified embodiment may be combined so as to always obtain both an in-phase output signal and a reverse-phase output signal.

The effect of the embodiment 4 will be described. In the complex negative feedback frequency selection output device 1 shown in FIG. 11, as to, e.g., the phase on the first output terminal 4 with respect to the phase of the input signal supplied to the first input terminal 3, two cases can happen where the phase is a substantially “0 phase” and where the phase is a “n phase” with a specific resistance value R3 as a boundary as shown in FIG. 12. This phenomenon may cause a situation where it is difficult to use when a wide range of resistance values R3 is used. This problem is solved by a signal in phase with the signal applied to the first input terminal 3 being always output via the third output terminal 204 in the embodiment 4.

With the oscillation circuit 310 shown in FIG. 14, at least the sharpness of the oscillation output can be improved by adjusting the feedback rate p1 of the second in-phase feedback circuit 325 without changing the circuit constants of the complex negative feedback frequency selection output circuit. Further, automatic adjustment can be performed so that at least the sharpness of the oscillation output becomes a target set value.

Another modified embodiment may have a circuit configuration wherein in the automatic adjustment circuit 100 shown in FIG. 13, the third analog adder circuit 112 is removed from between the terminal T140 and the terminal T150, and the terminal T140 and the terminal T150 are directly connected.

### REFERENCE SIGNS LIST

1 Composite negative feedback frequency selection output circuit
2 Reference terminal
3 First input terminal
4 First output terminal
5 Second output terminal
6 First power distribution circuit
7 First operational amplifying circuit
8 Second differential input amplifying circuit
9 Second power distribution circuit
10 Third power distribution circuit
11 Resonator circuit
12 Compensating circuit
13 First analog adder circuit
14 Fourth power distribution circuit
15 First equivalent load circuit
16 Fifth power distribution circuit
17 First virtual analog addition point
23 Power distribution negative feedback circuit
24 First feedback circuit
40 First in-phase current path
50 First reverse-phase current path
60 First negative feedback current path
70 First negative feedback current path loop
80 Second negative feedback current path loop
e0, e1, e2, e3 Signal level
μ1, μ2 Gain

1. A complex negative feedback frequency selection output circuit comprising:
a power distribution negative feedback circuit that has one input terminal, two output terminals, and a feedback terminal and outputs onto said two output terminals a signal in phase with a feedback processed signal obtained by negative feeding back a feedback signal supplied to said feedback terminal to an input frequency signal supplied to said input terminal and a signal opposite in phase to said feedback processed signal, respectively;
a selective relay circuit that relays only the residual components of the output on one of said output terminals with a rejected frequency band being left out;
a real number component relay circuit that relays at least a real number component of the output on the other of said output terminals; and
a feedback circuit that relays one of a difference signal and a sum signal of the relayed output of said selective relay circuit and the relayed output of said real number component relay circuit, as said feedback signal to said feedback terminal.

2. A complex negative feedback frequency selection output circuit according to claim 1, wherein said power distribution negative feedback circuit is constituted by a differential pair amplifying circuit containing first and second transistors, and
wherein one and the other of control terminals of said first and second transistors are respectively said input terminal and said feedback terminal, and of all terminals except a common connection terminal of said first and second transistors, two current path forming terminals are said two output terminals.

3. A complex negative feedback frequency selection output circuit according to claim 1, wherein said power distribution negative feedback circuit is constituted by a two-stage amplifying circuit comprising a front stage having a positive input end and a negative input end as said input terminal and said feedback terminal and that outputs a difference signal between two input signals to said positive input end and said negative input end; and a rear stage that generates a signal in phase with, and a signal opposite in phase to, the difference signal output of said front stage on two output ends thereof respectively, said two output ends of said rear stage being said two output terminals.

4. A complex negative feedback frequency selection output circuit according to claim 1, wherein said power distribution negative feedback circuit is constituted by an amplifying transformer circuit comprising a front stage having a positive input end and a negative input end as said input terminal and said feedback terminal and that outputs a difference signal between two input signals to said positive input end and said negative input end; and a transformer circuit formed of a primary winding that has the difference signal output of said front stage inputted thereto, thereby being excited and a secondary winding having its middle point connected to reference potential and that outputs a signal in phase with, and a signal opposite in phase to, the input signal to said primary winding onto two output ends thereof respectively, said two output ends of said secondary winding being said two output terminals.

5. A complex negative feedback frequency selection output circuit according to claim 1, wherein said power distribution negative feedback circuit is constituted by a transformer circuit comprising primary and secondary windings that each have their middle point connected to reference potential, and both ends of said primary winding are said input terminal and said feedback terminal, and both ends of said secondary winding are said two output terminals respectively.

6. A complex negative feedback frequency selection output circuit according to claim 1, wherein said power distribution negative feedback circuit is constituted by a four-terminal network formed of at least five delay elements and having two input ends and two output ends, and said two input ends are said input terminal and said feedback terminal, and said two output ends are said two output terminals.

7. A complex negative feedback frequency selection output circuit according to claim 1, wherein said power distribution negative feedback circuit comprises a first operational amplifier having a non-inverting input terminal connected to said input terminal, an inverting input terminal connected to said feedback terminal, and a first output end connected to one of said output terminals; and a second operational amplifier having an inverting input terminal connected to said input terminal, a non-inverting input terminal connected to said feedback terminal, and a second output end connected to the other of said output terminals.

8. A complex negative feedback frequency selection output circuit according to claim 1, wherein said selective relay circuit comprises one of an anti-resonant circuit having an anti-resonant characteristic, a band-pass filter, and a band-blocking filter.

9. A complex negative feedback frequency selection output circuit according to claim 1, wherein said real number component relay circuit is constituted by a pure resistor circuit.

10. A complex negative feedback frequency selection output circuit according to claim 1, wherein said real number component relay circuit has a frequency characteristic and relays an imaginary number component as well.

11. A complex negative feedback frequency selection output circuit according to claim 1, wherein said feedback circuit has a phase characteristic.

12. An adjustable complex negative feedback frequency selection output circuit comprising:
a negative feedback power distribution circuit that has one input terminal, two output terminals, and a feedback terminal and outputs onto said two output terminals a signal in phase with a feedback processed signal obtained by negative feeding back a feedback signal supplied to said feedback terminal to an input frequency signal supplied to said input terminal and a signal opposite in phase to said feedback processed signal, respectively;
a selective relay circuit that relays only the residual components of the output on one of said output terminals with a rejected frequency band being left out;
a real number component relay circuit that relays at least a real number component of the output on the other of said output terminals;
a feedback circuit that relays one of a difference signal and a sum signal of the relayed output of said selective relay circuit and the relayed output of said real number component relay circuit, as said feedback signal to said feedback terminal; and
loop gain adjusting means that adjusts the loop gain of a circuit loop from said input terminal to said feedback terminal.

13. An adjustable complex negative feedback frequency selection output circuit according to claim 12, wherein said loop gain adjusting means is a variable gain amplifier placed in said circuit loop.

14. An adjustable complex negative feedback frequency selection output circuit according to claim 13, wherein said variable gain amplifier is inserted in said feedback circuit.

15. An adjustable complex negative feedback frequency selection output circuit according to claim 13, wherein said variable gain amplifier is included in said negative feedback power distribution circuit.

16. An adjustable complex negative feedback frequency selection output circuit according to claim 12, wherein said loop gain adjusting means is one of manual and automatic setting variable attenuators that is inserted in said feedback circuit.

17. An adjustable complex negative feedback frequency selection output circuit according to claim 12, wherein said loop gain adjusting means is one of manual and automatic setting variable resistors that is included in said real number component relay circuit.

18. An adjustable complex negative feedback frequency selection output circuit according to claim 12, wherein said loop gain adjusting means is one of manual and automatic setting potential adjusting circuits that is included in said feedback circuit.

19. An oscillation circuit comprising:
a complex negative feedback frequency selection output circuit according to claim 1; and
a positive feedback path that feeds back as said input frequency signal one of signals output from said two output terminals of said complex negative feedback frequency selection output circuit or said adjustable complex negative feedback frequency selection output circuit.

20. An oscillation circuit according to claim 19, wherein said positive feedback path has a phase shift characteristic.

21. An oscillation circuit comprising:
an adjustable complex negative feedback frequency selection output circuit according to claim 12; and
a positive feedback path that feeds back as said input frequency signal one of signals output from said two output terminals of said complex negative feedback frequency selection output circuit or said adjustable complex negative feedback frequency selection output circuit.

22. An oscillation circuit according to claim 21, wherein said positive feedback path has a phase shift characteristic.
